(19) United States
(12) Patent Application Publication
(10) Pub. No.: US 2024/0431119 A1
(43) Pub. Date: Dec. 26, 2024

(54) SEMICONDUCTOR DEVICE

(71) Applicant: Samsung Electronics Co., Ltd., Suwon-si (KR)

(72) Inventors: Kilho Lee, Suwon-si (KR); Yongjae Kim, Suwon-si (KR); Junho Park, Suwon-si (KR)

(21) Appl. No.: 18/405,141

(22) Filed: Jan. 5, 2024

(30) Foreign Application Priority Data
Jun. 20, 2023 (KR) 10-2023-0079098

(51) Int. Cl. H10B 61/00

(52) U.S. Cl. CPC H10B 61/00

(57) ABSTRACT

A semiconductor device may include a lower dielectric layer on a substrate, data storage patterns on the lower dielectric layer and spaced apart from each other in first and second directions, a cell dielectric layer on the lower dielectric layer and on the data storage patterns, voids in the cell dielectric layer and between ones of the data storage patterns, upper conductive contacts respectively on the data storage patterns and spaced apart from each other in the first and second directions, and upper conductive lines on the upper conductive contacts and spaced apart from each other in the second direction and extending in the first direction. Each of the upper conductive lines may be electrically connected to respective ones of the upper conductive contacts. The respective ones of the upper conductive contacts may be spaced apart from each other in the first direction.

### CROSS-REFERENCE TO RELATED APPLICATION

This U.S. nonprovisional application claims priority under 35 U.S.C. § 119 to Korean Patent Application No. 10-2023-0079098 filed on Jun. 20, 2023 in the Korean Intellectual Property Office, the disclosure of which is hereby incorporated by reference in its entirety.

### BACKGROUND

The present inventive concepts relate to a semiconductor device and a method of fabricating the same, and more particularly, to a semiconductor device including a magnetic tunnel junction and a method of fabricating the same.

As electronic products trend toward high speed and/or low power consumption, high speed and low operating voltages are increasingly needed for semiconductor memory devices incorporated in the electronic products. In order to meet these needs, magnetic memory devices have been developed as semiconductor memory devices. Because magnetic memory devices operate at high speeds and have nonvolatile characteristics, they have attracted considerable attention as next-generation semiconductor memory devices.

In general, the magnetic memory device may include a magnetic tunnel junction (MTJ) pattern. The magnetic tunnel junction pattern includes two magnetic structures and a dielectric layer interposed therebetween. The resistance of the magnetic tunnel junction pattern varies depending on magnetization directions of the two magnetic structures. For example, the magnetic tunnel junction pattern has high resistance when the magnetization directions of the two magnetic structures are anti-parallel and low resistance when the magnetization directions of the two magnetic structures are parallel. The magnetic memory device may write and read data using the resistance difference between the high and low resistances of the magnetic tunnel junction pattern.

According to various demands of the electronics industry, diverse studies are being conducted on semiconductor devices having an embedded structure in which a magnetic tunnel junction pattern is disposed between metal lines.

### SUMMARY

Some embodiments of the present inventive concepts provide a semiconductor device capable of minimizing process defects and a method of fabricating the same.

Some embodiments of the present inventive concepts provide a semiconductor device capable of easily achieving high integration and a method of fabricating the same.

According to some embodiments of the present inventive concepts, a semiconductor device may include a lower dielectric layer on a substrate, a plurality of data storage patterns on the lower dielectric layer and spaced apart from each other in a first direction and a second direction that are parallel to a top surface of the substrate, wherein the first and second directions intersect each other, a cell dielectric layer on the lower dielectric layer and on the data storage patterns, a plurality of voids in the cell dielectric layer and between ones of the data storage patterns, a plurality of upper conductive contacts respectively on the data storage patterns and spaced apart from each other in the first direction and the second direction, and a plurality of upper conductive lines on the upper conductive contacts and spaced apart from each other in the second direction, wherein the upper conductive lines extend in the first direction. Each of the upper conductive lines may be electrically connected to respective ones of the upper conductive contacts. The respective ones of the upper conductive contacts may be spaced apart from each other in the first direction.

According to some embodiments of the present inventive concepts, a semiconductor device may include a lower dielectric layer on a substrate, a plurality of data storage patterns on the lower dielectric layer and spaced apart from each other in a first direction parallel to a top surface of the substrate, a cell dielectric layer on the lower dielectric layer and on the data storage patterns, a plurality of voids in the cell dielectric layer and between ones of the data storage patterns, a plurality of upper conductive contacts respectively on the data storage patterns and spaced apart from each other in the first direction, and an upper conductive line that is on the upper conductive contacts and extends in the first direction. The upper conductive contacts may extend into an upper portion of the cell dielectric layer and may be respectively electrically connected to the data storage patterns. The upper conductive line may be electrically connected to the upper conductive contacts.

According to some embodiments of the present inventive concepts, a semiconductor device may include a lower dielectric layer on a substrate, a plurality of data storage patterns on the lower dielectric layer and spaced apart from each other in a first direction parallel to a top surface of the substrate, a cell dielectric layer on the lower dielectric layer and on the data storage patterns, a plurality of voids in the cell dielectric layer, a plurality of upper conductive contacts respectively on the data storage patterns and spaced apart from each other in the first direction, and an upper conductive line that is on the upper conductive contacts and extends in the first direction. The upper conductive line may be electrically connected to the upper conductive contacts. The plurality of voids may be free of overlap with the upper conductive contacts in a second direction perpendicular to the top surface of the substrate.

### BRIEF DESCRIPTION OF THE DRAWINGS

FIG. 1 illustrates a circuit diagram showing a unit memory cell of a semiconductor device according to some embodiments of the present inventive concepts.

FIG. 2 illustrates a plan view showing a semiconductor device according to some embodiments of the present inventive concepts.

FIGS. 3A, 3B, 3C, and 3D illustrate cross-sectional views respectively taken along lines A-A′, B-B′, C-C′, and D-D′ of FIG. 2.

FIGS. 4A and 4B illustrate cross-sectional views showing examples of a magnetic tunnel junction pattern in a semiconductor device according to some embodiments of the present inventive concepts.

FIGS. 5A, 5B, 5C, 5D, 6A, 6B, 6C, 6D, 7A, 7B, 7C, 7D, 8A, 8B, 8C, 8D, 9A, 9B, 9C, and 9D illustrate cross-sectional views showing a method of fabricating a semiconductor device according to some embodiments of the present inventive concepts.

FIG. 10 illustrates a plan view showing a semiconductor device according to some embodiments of the present inventive concepts.

FIGS. 11A, 11B, and 11C illustrate cross-sectional views respectively taken along lines A-A′, B-B′, and C-C′ of FIG. 10.

### DETAILED DESCRIPTION

The following will now describe in detail example embodiments of the present inventive concepts with reference to the accompanying drawings.

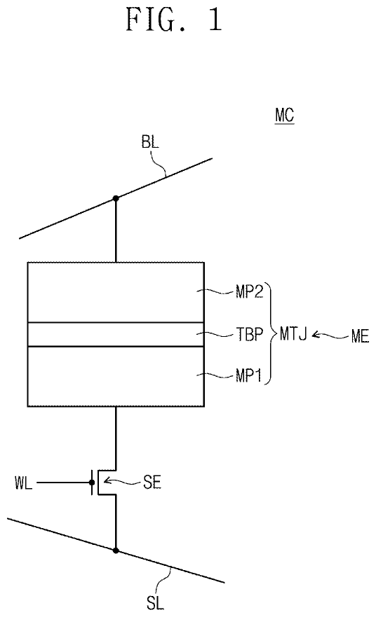

FIG. 1 illustrates a circuit diagram showing a unit memory cell of a semiconductor device according to some embodiments of the present inventive concepts.

Referring to FIG. 1, a unit memory cell MC may include a memory element ME and a selection element SE. The memory element ME and the selection element SE may be electrically connected in series to each other. The memory element ME may be connected between a bit line BL and the selection element SE. The selection element SE may be connected between the memory element ME and a source line SL, and may be controlled by a word line WL. The selection element SE may include, for example, a bipolar transistor or a metal oxide semiconductor field effect transistor (MOSFET). As used herein, “an element A is connected to an element B” (or similar language) means that the element A is physically and/or electrically connected to the element B.

The memory element ME may include a magnetic tunnel junction pattern MTJ including first and second magnetic patterns MP1 and MP2 and a tunnel barrier pattern TBP between the first and second magnetic patterns MP1 and MP2. One of the first and second magnetic patterns MP1 and MP2 may be a reference magnetic pattern having a magnetization direction that is fixed regardless of an external magnetic field under a normal use environment. The other of the first and second magnetic patterns MP1 and MP2 may be a free magnetic pattern whose magnetization direction is changed due to an external magnetic field between two stable magnetization directions. The magnetic tunnel junction pattern MTJ may have an electrical resistance whose value is much greater when the magnetization directions of the reference magnetic pattern and the free magnetic pattern are anti-parallel to each other compared to when the magnetization directions of the reference magnetic pattern and the free magnetic pattern are parallel to each other. For example, the electrical resistance of the magnetic tunnel junction pattern MTJ may be controlled by changing the magnetization direction of the free magnetic pattern. The memory element ME may use the difference in electrical resistance dependent on the magnetization directions of the reference magnetic pattern and the free magnetic pattern, which mechanism may cause the unit memory cell MC to store data therein.

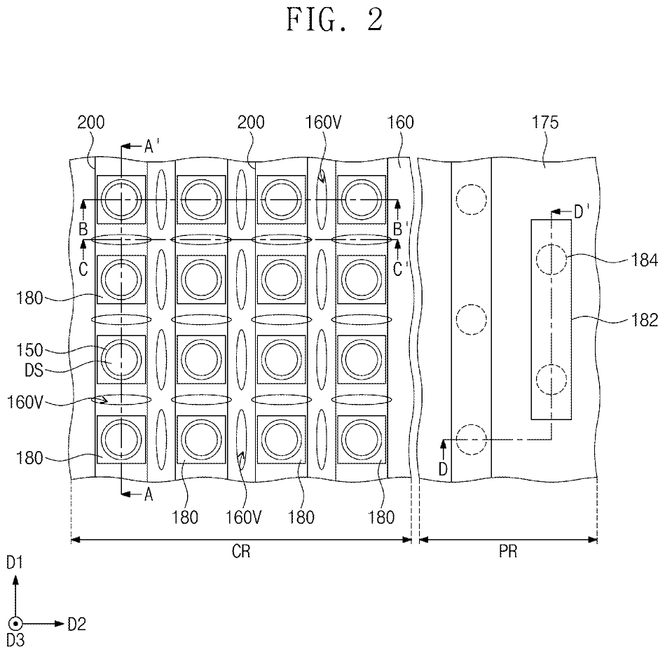

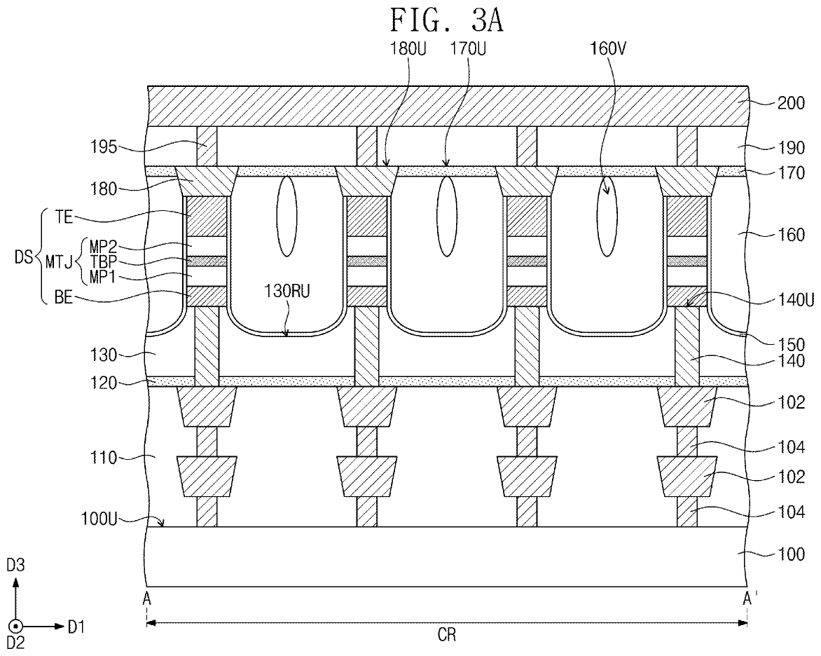

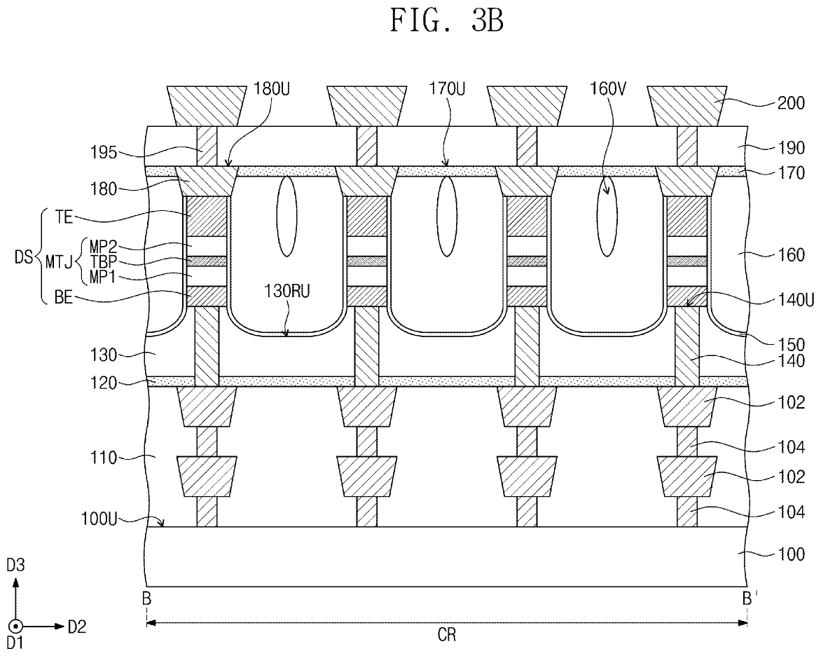

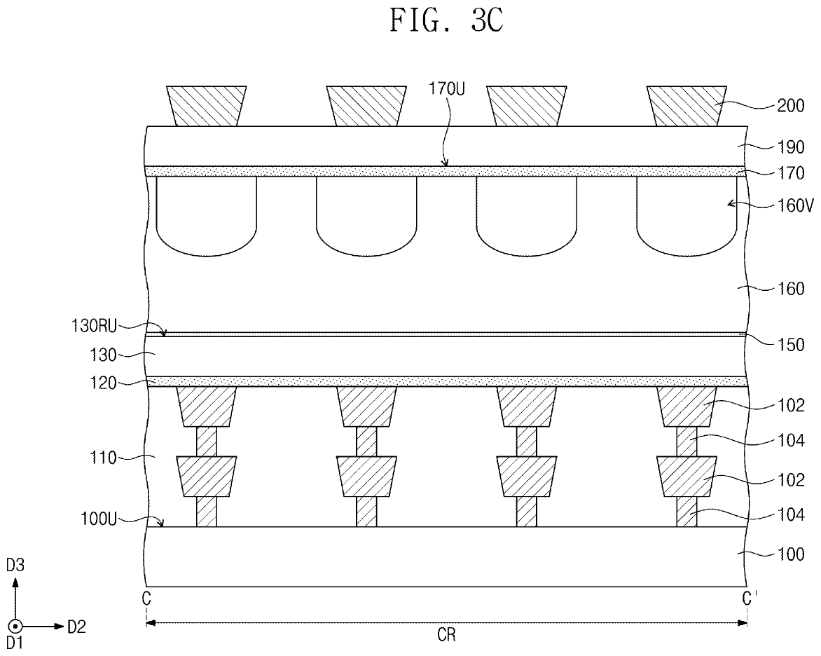

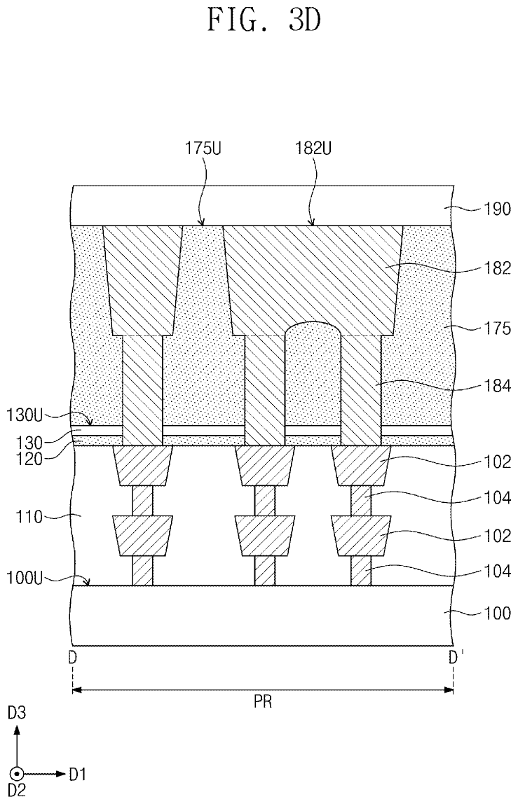

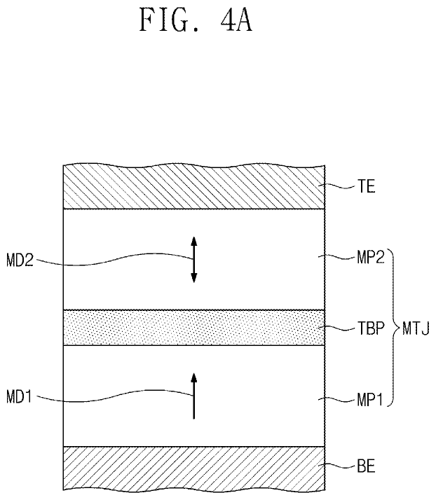

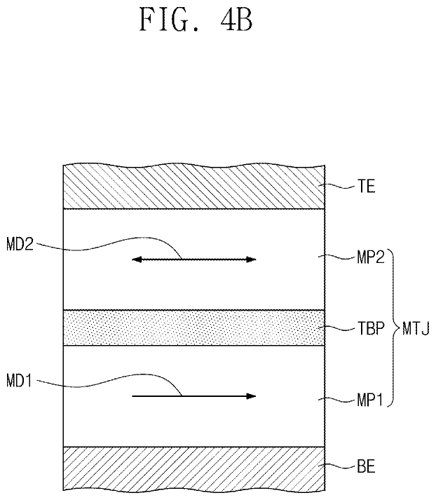

FIG. 2 illustrates a plan view showing a semiconductor device according to some embodiments of the present inventive concepts. FIGS. 3A, 3B, 3C, and 3D illustrate cross-sectional views respectively taken along lines A-A′, B-B′, C-C′, and D-D′ of FIG. 2. FIGS. 4A and 4B illustrate cross-sectional views showing examples of a magnetic tunnel junction pattern in a semiconductor device according to some embodiments of the present inventive concepts.

Referring to FIGS. 2 and 3A to 3D, a substrate 100 may be provided which includes a cell region CR and a peripheral region PR. The substrate 100 may be a semiconductor substrate including silicon (Si), silicon on insulator (SOI), silicon-germanium (SiGe), germanium (Ge), or gallium-arsenic (GaAs). The cell region CR may be one area of the substrate 100 on which the memory cells MC of FIG. 1 are provided, and the peripheral region PR may be another area of the substrate 100 on which peripheral circuits for driving the memory cells MC are provided.

A wiring structure 102 and 104 may be disposed on the substrate 100. The wiring structure 102 and 104 may be disposed on the cell region CR and the peripheral region PR of the substrate 100. The wiring structure 102 and 104 may include wiring lines 102 vertically spaced apart from the substrate 100 and wiring contacts 104 connected to the wiring lines 102. The wiring lines 102 may be spaced apart from a top surface 100U of the substrate 100 along a direction perpendicular to the top surface 100U of the substrate 100 (e.g., a third direction D3). The wiring contacts 104 may be disposed between the substrate 100 and the wiring lines 102. Each of the wiring lines 102 may be electrically connected to the substrate 100 through a corresponding one of the wiring contacts 104. The wiring lines 102 and the wiring contacts 104 may include metal (e.g., copper). As used herein, the terms “corresponding” and “correspondingly” may be used interchangeably with the terms “respective” and “respectively”, unless the context clearly indicates otherwise.

Selection elements (e.g., see SE of FIG. 1) may be disposed on the cell region CR of the substrate 100, and peripheral transistors constituting the peripheral circuits may be disposed on the peripheral region PR of the substrate 100. The selection elements and the peripheral transistors may be, for example, field effect transistors. Each of the wiring lines 102 may be electrically connected through a corresponding one of the wiring contacts 104 to one terminal (e.g., a source terminal, a drain terminal, or a gate terminal) of a corresponding one of either the selection elements or the peripheral transistors.

A wiring dielectric layer 110 may be disposed on the substrate 100 to be on (e.g., to cover) the wiring structure 102 and 104. The wiring dielectric layer 110 may be disposed on the cell region CR of the substrate 100, and may extend onto the peripheral region PR of the substrate 100. The wiring dielectric layer 110 may expose top surfaces of uppermost ones of the wiring lines 102. That is, the top surfaces of the uppermost ones of the wiring lines 102 may be free or devoid of the wiring dielectric layer 110 thereon. For example, the wiring dielectric layer 110 may have a top surface substantially coplanar with those of the uppermost wiring lines 102. The wiring dielectric layer 110 may include, for example, silicon oxide, silicon nitride, and/or silicon oxynitride.

A first lower dielectric layer 120 may be disposed on the wiring dielectric layer 110, and may cover or overlap the exposed top surfaces of the uppermost wiring lines 102. The first lower dielectric layer 120 may be disposed on the wiring dielectric layer 110 on the cell region CR, and may extend onto the wiring dielectric layer 110 on the peripheral region PR. The first lower dielectric layer 120 may include, for example, silicon oxide, silicon nitride, and/or silicon oxynitride.

A second lower dielectric layer 130 may be disposed on the first lower dielectric layer 120. The second lower dielectric layer 130 may be disposed on the first lower dielectric layer 120 on the cell region CR, and may extend onto the first lower dielectric layer 120 on the peripheral region PR. On the cell region CR and the peripheral region PR, the first lower dielectric layer 120 may be interposed between the wiring dielectric layer 110 and the second lower dielectric layer 130. The second lower dielectric layer 130 may include, for example, silicon oxide, silicon nitride, and/or silicon oxynitride. The first lower dielectric layer 120 and the second lower dielectric layer 130 may constitute a lower dielectric layer.

Data storage patterns DS may be disposed on the second lower dielectric layer 130 on the cell region CR. The data storage patterns DS may be spaced apart from each other in a first direction D1 and a second direction D2 that intersect each other and are parallel to the top surface 100U of the substrate 100. That is, the first and second directions D1 and D2 may intersect each other and may each be parallel to the top surface 100U of the substrate 100, and the data storage patterns DS may be spaced apart from each other in the first and second directions D1 and D2. The second lower dielectric layer 130 on the cell region CR may have a recessed top surface 130RU that is recessed toward the substrate 100 between the data storage patterns DS. For example, a first portion of the second lower dielectric layer 130 that is on the cell region CR may have the recessed top surface 130RU. The second lower dielectric layer 130 on the peripheral region PR may have a top surface 130U located at a height lower than that of the recessed top surface 130RU of the second lower dielectric layer 130 on the cell region CR. For example, a second portion of the second lower dielectric layer 130 that is on the peripheral region PR may have the top surface 130U. In this description, the term “height” may indicate a distance measured from the top surface 100U of the substrate 100 in a third direction D3 perpendicular to the top surface 100U of the substrate 100. In other words, the term “height” may indicate, in a non-limiting example, a distance in the third direction D3 (also referred to as a vertical direction), with the top surface 100U of the substrate 100 providing a base reference plane.

Lower electrode contacts 140 may be disposed in the second lower dielectric layer 130 on the cell region CR, and may be spaced apart from each other in the first direction D1 and the second direction D2. The lower electrode contacts 140 may be correspondingly disposed below and electrically connected to the data storage patterns DS. For example, the lower electrode contacts 140 may respectively be on bottom surfaces of the data storage patterns DS and may respectively be electrically connected to the data storage patterns DS. Each of the lower electrode contacts 140 may penetrate (i.e., extend into) the first and second lower dielectric layers 120 and 130 on the cell region CR, and may be connected to a corresponding one of the uppermost wiring lines 102. Each of the data storage patterns DS may be electrically connected to one terminal (e.g., a drain terminal) of a corresponding selection element (e.g., see SE of FIG. 1) through a corresponding lower electrode contact 140 and a corresponding uppermost wiring line 102.

The lower electrode contacts 140 may have top surfaces 140U located at a height higher than that of the recessed top surface 130RU of the second lower dielectric layer 130 on the cell region CR. The lower electrode contacts 140 may include at least one selected from doped semiconductor materials (e.g., doped silicon), metals (e.g., tungsten, titanium, and/or tantalum), metal-semiconductor compounds (e.g., metal silicide), and conductive metal nitrides (e.g., titanium nitride, tantalum nitride, and/or tungsten nitride).

Each of the data storage patterns DS may include a bottom electrode BE, a magnetic tunnel junction pattern MTJ, and a top electrode TE that are sequentially stacked in the third direction D3 on the second lower dielectric layer 130. The magnetic tunnel junction pattern MTJ may be interposed between the bottom electrode BE and the top electrode TE. The lower electrode contacts 140 may be correspondingly connected to the bottom electrodes BE of the data storage patterns DS. The magnetic tunnel junction pattern MTJ may include a first magnetic pattern MP1, a second magnetic pattern MP2, and a tunnel barrier pattern TBP between the first magnetic pattern MP1 and the second magnetic pattern MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP. The bottom electrode BE may include, for example, conductive metal nitride (e.g., titanium nitride or tantalum nitride). The top electrode TE may include at least one selected from metal (e.g., Ta, W, Ru, or Ir) and conductive metal nitride (e.g., TiN).

Referring to FIGS. 4A and 4B, the first magnetic pattern MP1 may be a reference layer (e.g., a reference magnetic pattern) having a magnetization direction MD1 that is fixed in one direction, and the second magnetic pattern MP2 may be a free layer (e.g., a free magnetic pattern) having a magnetization direction MD2 that can be changed to be parallel or antiparallel to the magnetization direction MD1 of the first magnetic pattern MP1. FIGS. 4A and 4B show an example in which the second magnetic pattern MP2 is a free layer, but the present inventive concepts are not limited thereto. Differently from that shown in FIGS. 4A and 4B, the first magnetic pattern MP1 may be the free layer and the second magnetic pattern MP2 may be the reference layer.

Referring to FIG. 4A, for example, the magnetization directions MD1 and MD2 of the first and second magnetic patterns MP1 and MP2 may be perpendicular to an interface between the tunnel barrier pattern TBP and the second magnetic pattern MP2. In this case, each of the first and second magnetic patterns MP1 and MP2 may include at least one selected from an intrinsic perpendicular magnetization material and an extrinsic perpendicular magnetization material. The intrinsic perpendicular magnetization material may include a material having a perpendicular magnetization property found even in the absence of an external factor. The intrinsic perpendicular magnetization material may include at least one selected from a perpendicular magnetic material (e.g., CoFeTb, CoFeGd, CoFeDy), a perpendicular magnetic material having an L10 structure, CoPt of a hexagonal close-packed (HCP) lattice structure, and a perpendicular magnetic structure. The perpendicular magnetic material having the L10 structure may include at least one selected from FePt of the L10 structure, FePd of the L10 structure, CoPd of the L10 structure, and CoPt of the L10 structure. The perpendicular magnetic structure may include magnetic layers and non-magnetic layers that are alternately and repeatedly stacked. For example, the perpendicular magnetic structure may include at least one selected from (Co/Pt)n, (CoFe/Pt)n, (CoFe/Pd)n, (Co/Pd)n, (Co/Ni)n, (CoNi/Pt)n, (CoCr/Pt)n, and (CoCr/Pd)n (where n is the number of stacked layers). The extrinsic perpendicular magnetization material may include a material having an intrinsic horizontal magnetization property or a perpendicular magnetization property caused by an external factor. For example, the extrinsic perpendicular magnetization material may have a perpendicular magnetization property due to magnetic anisotropy induced by a junction between the tunnel barrier pattern TBP and the first magnetic pattern MP1 (or the second magnetic pattern MP2). The extrinsic perpendicular magnetization material may include, for example, CoFeB.

Referring to FIG. 4B, as another example, the magnetization directions MD1 and MD2 of the first and second magnetic patterns MP1 and MP2 may be parallel to the interface between the tunnel barrier pattern TBP and the second magnetic pattern MP2. In this case, each of the first and second magnetic patterns MP1 and MP2 may include a ferromagnetic material. The first magnetic pattern MP1 may further include an anti-ferromagnetic material for fixing a magnetization direction of the ferromagnetic material in the first magnetic pattern MP1.

Each of the first and second magnetic patterns MP1 and MP2 may include a Heusler alloy including Co. The tunnel barrier pattern TBP may include at least one selected from a magnesium (Mg) oxide layer, a titanium (Ti) oxide layer, an aluminum (Al) oxide layer, a magnesium-zinc (MgZn) oxide layer, and a magnesium-boron (MgB) oxide layer.

Referring back to FIGS. 2 and 3A to 3D, a capping dielectric layer 150 may be disposed on the second lower dielectric layer 130 on the cell region CR. The capping dielectric layer 150 may conformally cover or overlap a lateral surface (e.g., a side surface) of each of the data storage patterns DS and the recessed top surface 130RU of the second lower dielectric layer 130 on the cell region CR. When viewed in plan, the capping dielectric layer 150 may surround the lateral surface of each of the data storage patterns DS. The capping dielectric layer 150 may conformally cover or overlap lateral surfaces of the bottom electrode BE, the magnetic tunnel junction pattern MTJ, and the top electrode TE. When viewed in plan, the capping dielectric layer 150 may surround the lateral surfaces of the bottom electrode BE, the magnetic tunnel junction pattern MTJ, and the top electrode TE. The capping dielectric layer 150 may include nitride (e.g., silicon nitride).

A cell dielectric layer 160 may be disposed on the second lower dielectric layer 130 on the cell region CR, and may be on (e.g., may cover) the data storage patterns DS. The cell dielectric layer 160 may fill a space between the data storage patterns DS. The capping dielectric layer 150 may be interposed between the cell dielectric layer 160 and the lateral surface of each of the data storage patterns DS, and may extend between the cell dielectric layer 160 and the recessed top surface 130RU of the second lower dielectric layer 130 on the cell region CR. The cell dielectric layer 160 may include, for example, silicon oxide, silicon nitride, and/or silicon oxynitride. For example, the cell dielectric layer 160 may include tetraethyl orthosilicate (TEOS) oxide.

An upper dielectric layer 170 may be disposed on the cell dielectric layer 160 on the cell region CR. The upper dielectric layer 170 may include a material different from that of the cell dielectric layer 160. The upper dielectric layer 170 may include silicon nitride (e.g., SiCN).

A plurality of voids 160V may be disposed in the cell dielectric layer 160 and between the data storage patterns DS. The plurality of voids 160V may be disposed below the upper dielectric layer 170, and may be disposed on the second lower dielectric layer 130 and the capping dielectric layer 150. For example, the plurality of voids 160V may be between the upper dielectric layer 170 and the second lower dielectric layer 130. Each of the plurality of voids 160V may vertically overlap with the recessed top surface 130RU of the second lower dielectric layer 130 in the third direction D3. As used herein, “an element A overlaps an element B in a direction X” (or similar language) means that there is at least one line that extends in the direction X and intersects both the elements A and B. The plurality of voids 160V may be spaced apart from each other in the first direction D1 and the second direction D2 on the second lower dielectric layer 130. Ones of the plurality of voids 160V may be disposed between ones of the data storage patterns DS that are spaced apart from each other in the first direction D1. At least one of the plurality of voids 160V may be disposed between a pair of ones of the data storage patterns DS (e.g., a pair of adjacent ones of the data storage patterns DS) that are spaced apart from each other in the first direction D1. Others of the plurality of voids 160V may be disposed between ones of the data storage patterns DS that are spaced apart from each other in the second direction D2. At least one of the plurality of voids 160V may be disposed between another pair of ones of the data storage patterns DS (e.g., another pair of adjacent ones of the data storage patterns DS) that are spaced apart from each other in the second direction D2.

A peripheral dielectric layer 175 may be disposed on the second lower dielectric layer 130 on the peripheral region PR. The top surface 130U of the second lower dielectric layer 130 on the peripheral region PR may be located at a height lower than that of the recessed top surface 130RU of the second lower dielectric layer 130 on the cell region CR, and the peripheral dielectric layer 175 may be in contact with the top surface 130U of the second lower dielectric layer 130 on the peripheral region PR. The peripheral dielectric layer 175 may have a top surface 175U located at a height the same as that of a top surface 170U of the upper dielectric layer 170. The top surface 175U of the peripheral dielectric layer 175 may be coplanar with the top surface 170U of the upper dielectric layer 170.

The peripheral dielectric layer 175 may include a material different from that of the cell dielectric layer 160. The peripheral dielectric layer 175 may include a dielectric material whose dielectric constant (k) is less than that of the cell dielectric layer 160. The peripheral dielectric layer 175 may include a material different from that of the upper dielectric layer 170, and may include a dielectric material whose dielectric constant (k) is less than that of the upper dielectric layer 170. The cell dielectric layer 160 and the upper dielectric layer 170 may include a dielectric material whose dielectric constant (k) is greater than that of the peripheral dielectric layer 175. The peripheral dielectric layer 175 may include, for example, silicon oxide, silicon nitride, and/or silicon oxynitride. For example, the peripheral dielectric layer 175 may include a dielectric material, such as porous SiOC, whose dielectric constant (k) is equal to or less than 2.5 or 2.0.

Upper conductive contacts 180 may be disposed on the cell region CR. The upper conductive contacts 180 may be correspondingly disposed on the data storage patterns DS, and may be spaced apart from each other in the first direction D1 and the second direction D2. The upper conductive contacts 180 may be correspondingly connected to the data storage patterns DS. Each of the upper conductive contacts 180 may penetrate (i.e., extend into) the upper dielectric layer 170, an upper portion of the cell dielectric layer 160, and the capping dielectric layer 150, and may be connected to the top electrode TE of a corresponding one of the data storage patterns DS. The upper conductive contacts 180 may be correspondingly in contact with the top electrodes TE of the data storage patterns DS. The upper dielectric layer 170 may expose top surfaces 180U of the upper conductive contacts 180. That is, the top surfaces 180U of the upper conductive contacts 180 may be free or devoid of the upper dielectric layer 170 thereon. The top surfaces 180U of the upper conductive contacts 180 may be located at a height the same as that of the top surface 170U of the upper dielectric layer 170, and may be coplanar with the top surface 170U of the upper dielectric layer 170. The upper conductive contacts 180 may include a conductive material, such as metal (e.g., copper).

Peripheral conductive lines 182 may be disposed in the peripheral dielectric layer 175 and on the second lower dielectric layer 130 on the peripheral region PR. The peripheral dielectric layer 175 may be on (e.g., may cover) the peripheral conductive lines 182. The peripheral conductive lines 182 may have top surfaces 182U that are exposed without being covered with the peripheral dielectric layer 175. That is, the top surfaces 182U of the peripheral conductive lines 182 may free or devoid of the peripheral dielectric layer 175 thereon. The top surfaces 182U of the peripheral conductive lines 182 may be substantially coplanar with the top surface 175U of the peripheral dielectric layer 175. The top surfaces 182U of the peripheral conductive lines 182 may be located at a height the same as that of the top surface 175U of the peripheral dielectric layer 175. The top surfaces 182U of the peripheral conductive lines 182 may be located at a height the same as that of the top surfaces 180U of the upper conductive contacts 180 and that of the top surface 170U of the upper dielectric layer 170. The top surfaces 182U of the peripheral conductive lines 182 may be coplanar with the top surfaces 180U of the upper conductive contacts 180 and the top surface 170U of the upper dielectric layer 170.

Peripheral conductive contacts 184 may be disposed on the peripheral region PR and below the peripheral conductive lines 182. For example, the peripheral conductive contacts 184 may be on bottom surfaces of the peripheral conductive lines 182. The peripheral conductive contacts 184 may be electrically connected to the peripheral conductive lines 182. Each of the peripheral conductive contacts 184 may be in contact, without an interface, with a corresponding one of the peripheral conductive lines 182. Each of the peripheral conductive contacts 184 and its corresponding peripheral conductive line 182 may be connected to constitute a single unitary piece. Each of the peripheral conductive contacts 184 may penetrate (i.e., extend into) a lower portion of the peripheral dielectric layer 175. Each of the peripheral conductive contacts 184 may penetrate (i.e., extend into) the second lower dielectric layer 130 and the first lower dielectric layer 120 on the peripheral region PR, and may be electrically connected to a corresponding one of the uppermost wiring lines 102. Each of the peripheral conductive lines 182 may be electrically connected to one terminal (e.g., a source terminal, a drain terminal, or a gate terminal) of a corresponding peripheral transistor through corresponding peripheral conductive contacts 184 and corresponding uppermost wiring lines 102.

The peripheral conductive lines 182 and the peripheral conductive contacts 184 may include a conductive material, such as metal (e.g., copper). The upper conductive contacts 180, the peripheral conductive lines 182, and the peripheral conductive contacts 184 may include the same material.

An interlayer dielectric layer 190 may be disposed on the cell region CR and the peripheral region PR, and may be on (e.g., may cover) the top surface 170U of the upper dielectric layer 170, the top surfaces 180U of the upper conductive contacts 180, the top surface 175U of the peripheral dielectric layer 175, and the top surfaces 182U of the peripheral conductive lines 182. The interlayer dielectric layer 190 may be on (e.g., may cover) the top surface 170U of the upper dielectric layer 170, and may extend onto the top surfaces 180U of the upper conductive contacts 180. The interlayer dielectric layer 190 may be on (e.g., may cover) the top surface 175U of the peripheral dielectric layer 175, and may extend onto the top surfaces 182U of the peripheral conductive lines 182. The interlayer dielectric layer 190 may include, for example, silicon oxide, silicon nitride, and/or silicon oxynitride.

Upper vias 195 may be disposed in the interlayer dielectric layer 190 on the cell region CR. The upper vias 195 may be correspondingly disposed on the upper conductive contacts 180, and may be spaced apart from each other in the first direction D1 and the second direction D2. The upper vias 195 may be correspondingly connected to the upper conductive contacts 180. The upper vias 195 may penetrate (i.e., extend into) the interlayer dielectric layer 190 and may be correspondingly connected to the upper conductive contacts 180. The upper vias 195 may be correspondingly in contact with the top surfaces 180U of the upper conductive contacts 180. The upper vias 195 may include a conductive material, such as metal (e.g., copper).

Upper conductive lines 200 may be disposed on the interlayer dielectric layer 190 on the cell region CR. The upper conductive lines 200 may extend in the first direction D1, and may be spaced apart from each other in the second direction D2. Each of the upper conductive lines 200 may have a linear shape elongated in the first direction D1. For example, each of the upper conductive lines 200 may extend longitudinally in the first direction D1. As used herein, the term “longitudinally” indicates a longest dimension. Each of the upper conductive lines 200 may be connected to corresponding ones of the upper vias 195 that are spaced apart from each other in the first direction D1, and may be electrically connected through the corresponding upper vias 195 to corresponding ones of the upper conductive contacts 180 that are spaced apart from each other in the first direction D1. A bit line BL of FIG. 1 may be constituted by one of the upper conductive lines 200, corresponding upper vias 195 that are spaced apart from each other in the first direction D1, and corresponding upper conductive contacts 180 that are spaced apart from each other in the first direction D1. The upper conductive lines 200 may include a conductive material, such as metal (e.g., copper).

The upper conductive contacts 180 may be correspondingly disposed on the data storage patterns DS, and therefore, the upper conductive contacts 180 may be spaced horizontally (e.g., in the first direction D1 or the second direction D2) apart from the plurality of voids 160V between the data storage patterns DS. Each of the plurality of voids 160V may be disposed between a pair of ones of the upper conductive contacts 180 (e.g., a pair of adjacent ones of the upper conductive contacts 180) that are spaced apart from each other in the first direction D1 or the second direction D2. Each of the plurality of voids 160V may not overlap in the third direction D3 with any of the upper conductive contacts 180. That is, each of the plurality of voids 160V may be free of overlap with the upper conductive contacts 180 in the third direction D3.

Among the plurality of voids 160V, the voids 160V that are spaced apart from each other in the first direction D1 may be disposed between ones of the data storage patterns DS that are spaced apart from each other in the first direction D1 and between ones of the upper conductive contacts 180 that are spaced apart from each other in the first direction D1 (e.g., see FIG. 3A). Each of the upper conductive lines 200 may have a linear shape elongated in the first direction D1, and may overlap vertically (e.g., in the third direction D3) with the voids 160V that are spaced apart from each other in the first direction D1.

With high integration of a semiconductor device including the data storage patterns DS, the plurality of voids 160V may be formed in the cell dielectric layer 160 between the data storage patterns DS. When a conductive line, which penetrates (i.e., extends into) the upper dielectric layer 170 and an upper portion of the cell dielectric layer 160 and is elongated in the first direction D1, is formed between the data storage patterns DS that are spaced apart from each other in the first direction D1, the conductive line may be connected to the data storage patterns DS that are spaced apart from each other in the first direction D1, and may overlap vertically (e.g., in the third direction D3) with the voids 160V that are spaced apart from each other in the first direction D1. In this case, during the formation of the conductive lines, the voids 160V may be filled with a conductive material, and thus bridge failure (e.g., a bridging fault) may occur between the conductive lines that neighbor each other in the second direction D2.

According to the present inventive concepts, the upper conductive contacts 180 may be correspondingly disposed on the data storage patterns DS, and may be spaced apart from each other in the first direction D1 and the second direction D2. Therefore, the upper conductive contacts 180 may be spaced horizontally (e.g., in the first direction D1 or the second direction D2) apart from the plurality of voids 160V, and each of the plurality of voids 160V may not overlap in the third direction D3 with any of the upper conductive contacts 180. The plurality of voids 160V may be disposed below the upper dielectric layer 170 between the upper conductive contacts 180, and may overlap vertically (e.g., in the third direction D3) with the upper dielectric layer 170 between the upper conductive contacts 180. In this case, during the formation of the upper conductive contacts 180, the plurality of voids 160V may be blocked by the upper dielectric layer 170, and as a result, may be prevented from being filled with a conductive material. No bridge failure (e.g., no bridging fault) may thus occur between the upper conductive contacts 180.

Accordingly, a semiconductor device may be provided which is capable of easily achieving high integration and minimizing process defects according to embodiments of the present inventive concepts.

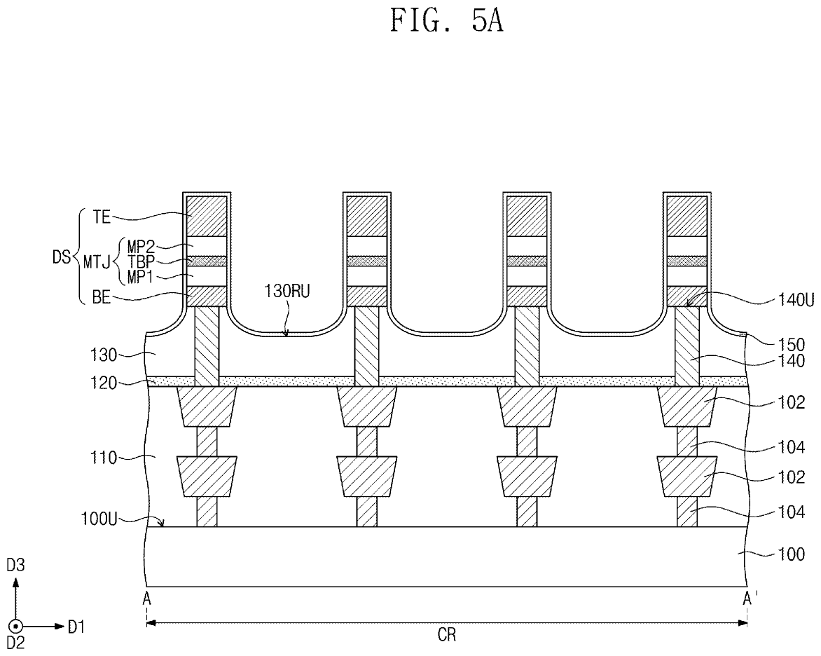

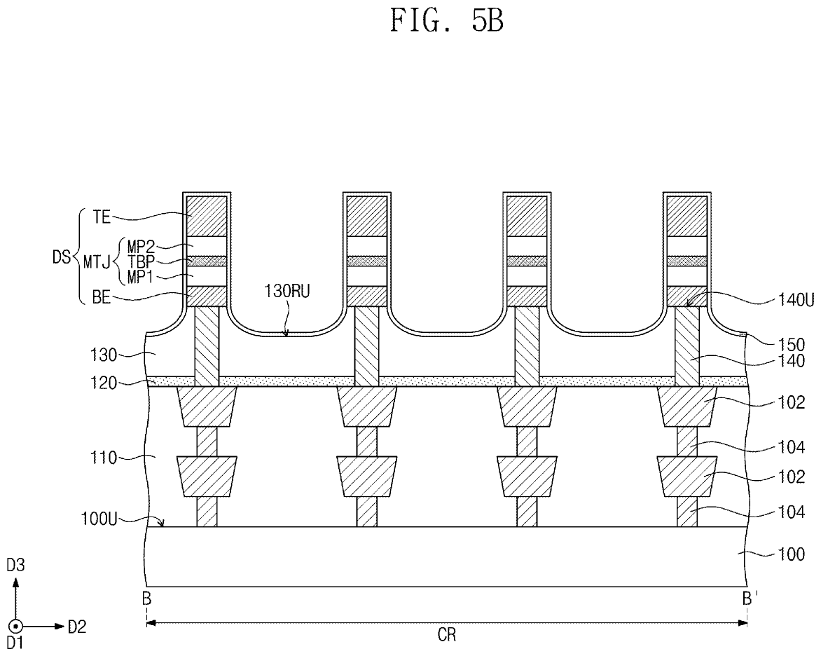

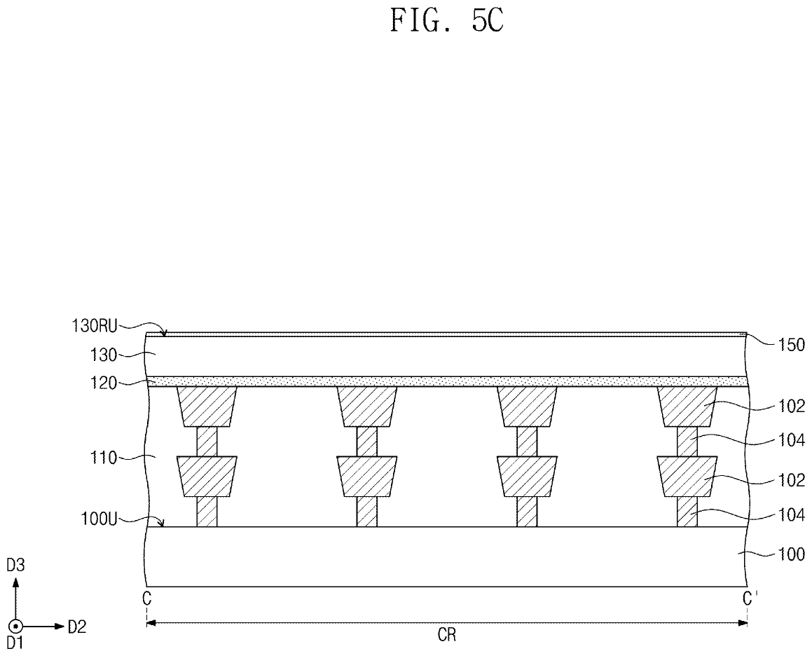

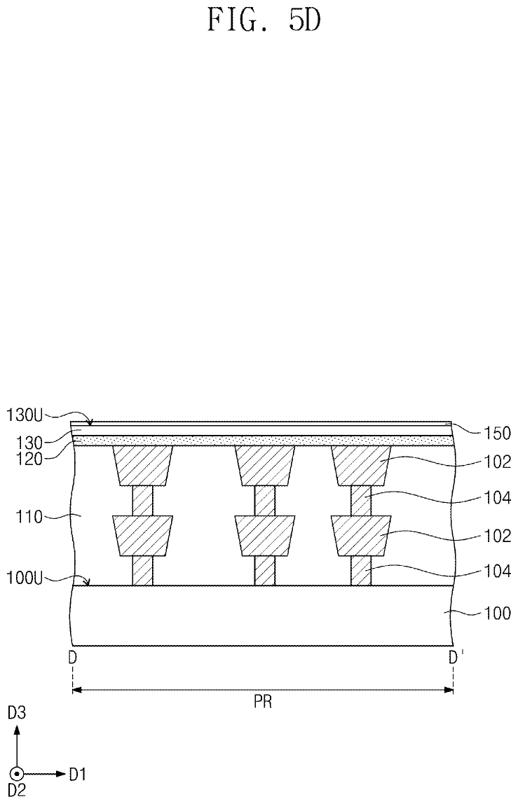

FIGS. 5A, 5B, 5C, 5D, 6A, 6B, 6C, 6D, 7A, 7B, 7C, 7D, 8A, 8B, 8C, 8D, 9A, 9B, 9C, and 9D illustrate cross-sectional views showing a method of fabricating a semiconductor device according to some embodiments of the present inventive concepts. FIGS. 5A, 6A, 7A, 8A, and 9A illustrate cross-sectional views taken along line A-A′ of FIG. 2. FIGS. 5B, 6B, 7B, 8B, and 9B illustrate cross-sectional views taken along line B-B′of FIG. 2. FIGS. 5C, 6C, 7C, 8C, and 9C illustrate cross-sectional views taken along line C-C′ of FIG. 2. FIGS. 5D, 6D, 7D, 8D, and 9D illustrate cross-sectional views taken along line D-D′ of FIG. 2. For brevity of description, redundant or repetitive descriptions that overlap with the discussion of the semiconductor device described with reference to FIGS. 1, 2, 3A to 3D, 4A, and 4B will be briefly mentioned or omitted.

Referring to FIGS. 2 and 5A to 5D, a substrate 100 may be provided which includes a cell region CR and a peripheral region PR. Selection elements (e.g., see SE of FIG. 1) and peripheral transistors may be formed on the substrate 100, and a wiring structure 102 and 104 may be formed on the selection elements and the peripheral transistors. The wiring structure 102 and 104 may include wiring lines 102 that are spaced vertically (e.g., in a third direction D3) apart from the substrate 100, and may also include wiring contacts 104 connected to the wiring lines 102. Each of the wiring lines 102 may be electrically connected through a corresponding one of the wiring contacts 104 to one terminal (e.g., a source terminal, a drain terminal, or a gate terminal) of a corresponding one of either the selection elements or the peripheral transistors.

A wiring dielectric layer 110 may be formed on the substrate 100, and may be on (e.g., may cover) the wiring structure 102 and 104. The wiring dielectric layer 110 may expose top surfaces of uppermost ones of the wiring lines 102.

A first lower dielectric layer 120 may be formed on the wiring dielectric layer 110, and may cover or overlap the exposed top surfaces of the uppermost wiring lines 102. The first lower dielectric layer 120 may be formed on the wiring dielectric layer 110 on the cell region CR, and may extend onto the wiring dielectric layer 110 on the peripheral region PR.

A second lower dielectric layer 130 may be formed on the first lower dielectric layer 120. The second lower dielectric layer 130 may be formed on the first lower dielectric layer 120 on the cell region CR, and may extend onto the first lower dielectric layer 120 on the peripheral region PR.

Lower electrode contacts 140 may be formed in the second lower dielectric layer 130 on the cell region CR. Each of the lower electrode contacts 140 may penetrate (i.e., extend into) the first and second lower dielectric layers 120 and 130 on the cell region CR, and may be electrically connected to one of the uppermost wiring lines 102. The formation of the lower electrode contacts 140 may include, for example, forming lower contact holes that penetrate (i.e., extend into) the first and second lower dielectric layers 120 and 130 on the cell region CR, forming a lower contact layer that fills the lower contact holes on the second lower dielectric layer 130, and planarizing the lower contact layer until a top surface of the second lower dielectric layer 130 is exposed. In the planarization process, the lower electrode contacts 140 may be correspondingly locally formed in the lower contact holes.

Data storage patterns DS may be formed on the second lower dielectric layer 130 on the cell region CR. The data storage patterns DS may be correspondingly formed on and electrically connected to the lower electrode contacts 140.

Each of the data storage patterns DS may include a bottom electrode BE, a magnetic tunnel junction pattern MTJ, and a top electrode TE that are sequentially stacked on the second lower dielectric layer 130. The magnetic tunnel junction pattern MTJ may include a first magnetic pattern MP1, a second magnetic pattern MP2, and a tunnel barrier pattern TBP between the first magnetic pattern MP1 and the second magnetic pattern MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP. The formation of the data storage patterns DS may include, for example, sequentially forming a bottom electrode layer and a magnetic tunnel junction layer on the second lower dielectric layer 130, forming a conductive mask pattern on the magnetic tunnel junction layer, and using the conductive mask pattern as an etching mask to sequentially etch the magnetic tunnel junction layer and the bottom electrode layer. The magnetic tunnel junction layer may include a first magnetic layer, a tunnel barrier layer, and a second magnetic layer that are sequentially stacked on the bottom electrode layer. The magnetic tunnel junction layer and the bottom electrode layer may be formed by, for example, a sputtering process, a chemical vapor deposition process, or an atomic layer deposition process.

The magnetic tunnel junction layer and the bottom electrode layer may be etched to respectively form the magnetic tunnel junction pattern MTJ and the bottom electrode BE. The etching of the magnetic tunnel junction layer may include using the conductive mask pattern as an etching mask to sequentially etch the second magnetic layer, the tunnel barrier layer, and the first magnetic layer. The second magnetic layer, the tunnel barrier layer, and the first magnetic layer may be etched to form the second magnetic pattern MP2, the tunnel barrier pattern TBP, and the first magnetic pattern MP1. The conductive mask pattern may remain on the magnetic tunnel junction pattern MTJ after the magnetic tunnel junction layer and the bottom electrode layer are etched, and the remainder of the conductive mask pattern may be defined as the top electrode TE.

An ion beam etching process that uses an ion beam may be used to perform an etching process for etching the magnetic tunnel junction layer and the bottom electrode layer. The ion beam may include inert ions. The etching process may recess an upper portion of the second lower dielectric layer 130 between the data storage patterns DS. Therefore, the second lower dielectric layer 130 on the cell region CR may have a recessed top surface 130RU that is recessed toward the substrate 100. The recessed top surface 130RU of the second lower dielectric layer 130 may be located at a height lower than that of top surfaces 140U of the lower electrode contacts 140. In addition, the etching process may recess an upper portion of the second lower dielectric layer 130 on the peripheral region PR. The second lower dielectric layer 130 on the peripheral region PR may have a top surface 130U located at a height lower than that of the recessed top surface 130RU of the second lower dielectric layer 130 on the cell region CR.

A capping dielectric layer 150 may be formed on the second lower dielectric layer 130 on the cell region CR, and may conformally cover or overlap a lateral surface of each of the data storage patterns DS. The capping dielectric layer 150 may conformally cover or overlap the recessed top surface 130RU of the second lower dielectric layer 130 on the cell region CR, and may extend onto the top surface 130U of the second lower dielectric layer 130 on the peripheral region PR.

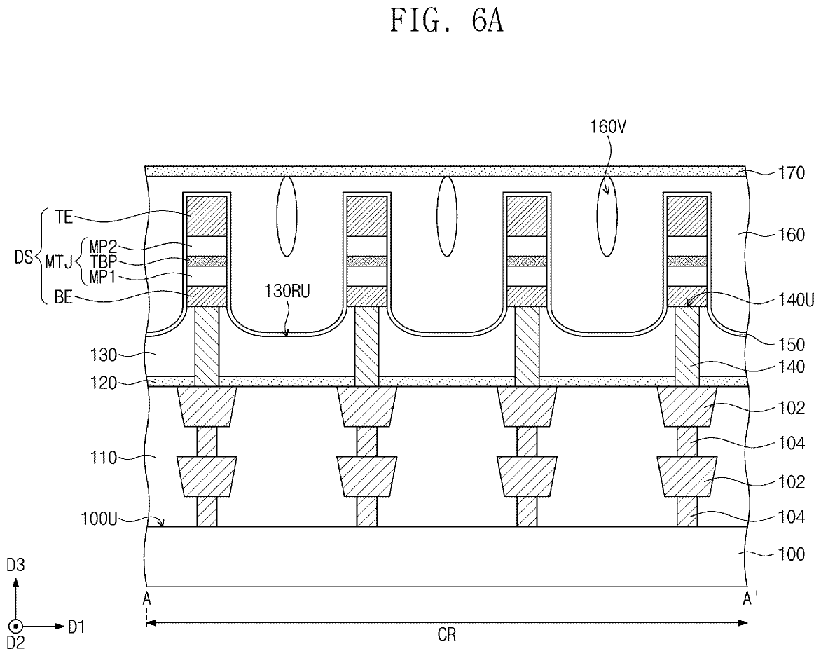

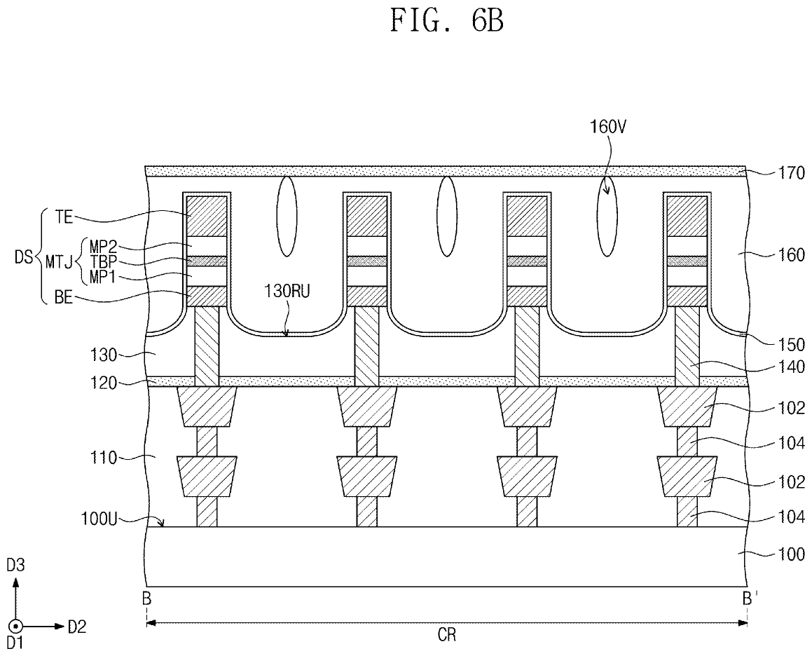

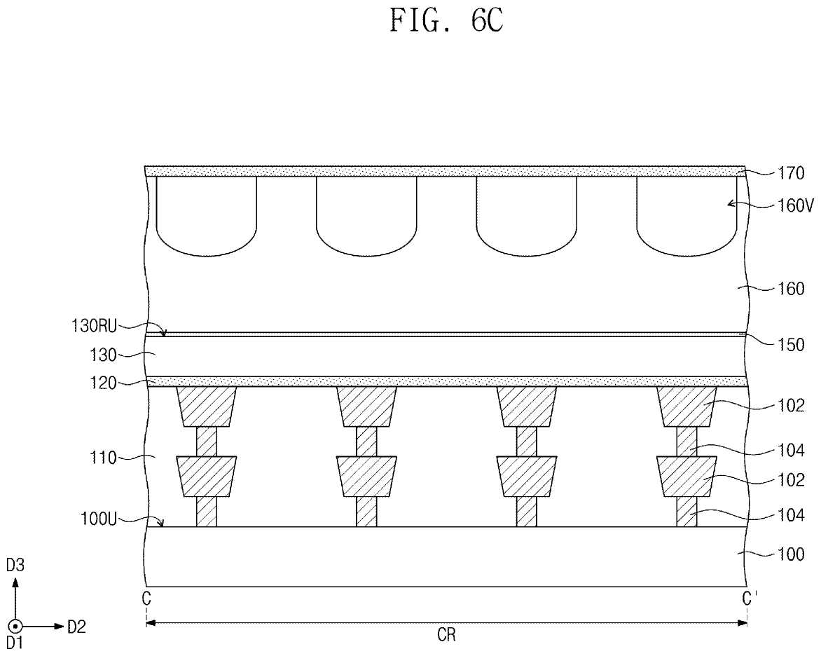

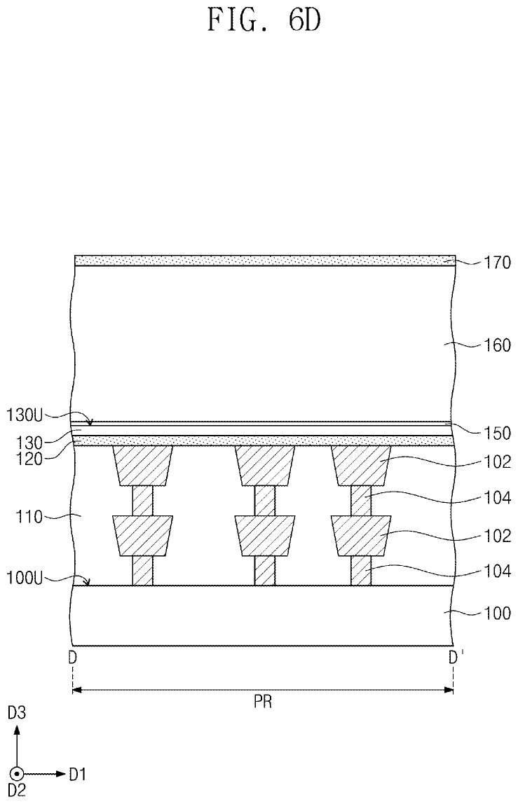

Referring to FIGS. 2 and 6A to 6D, a cell dielectric layer 160 may be formed on the capping dielectric layer 150. The cell dielectric layer 160 may be formed on the capping dielectric layer 150 on the cell region CR to be on (e.g., to cover) the data storage patterns DS and to fill a space between the data storage patterns DS. The cell dielectric layer 160 may extend onto the capping dielectric layer 150 on the peripheral region PR. The cell dielectric layer 160 may be formed by using, for example, a high density plasma chemical vapor deposition (HDP CVD) process.

An increase in integration of a semiconductor device may cause a reduction in distance between the data storage patterns DS, and as a result, the cell dielectric layer 160 may incompletely fill a space between the data storage patterns DS. Therefore, a plurality of voids 160V may be formed between the data storage patterns DS and in the cell dielectric layer 160 on the cell region CR. Each of the plurality of voids 160V may overlap vertically along the third direction D3 with the recessed top surface 130RU of the second lower dielectric layer 130 on the cell region CR.

An upper dielectric layer 170 may be formed on the cell dielectric layer 160. The upper dielectric layer 170 may be formed on the cell dielectric layer 160 on the cell region CR, and may extend onto the cell dielectric layer 160 on the peripheral region PR. The plurality of voids 160V may be disposed below the upper dielectric layer 170 on the cell region CR.

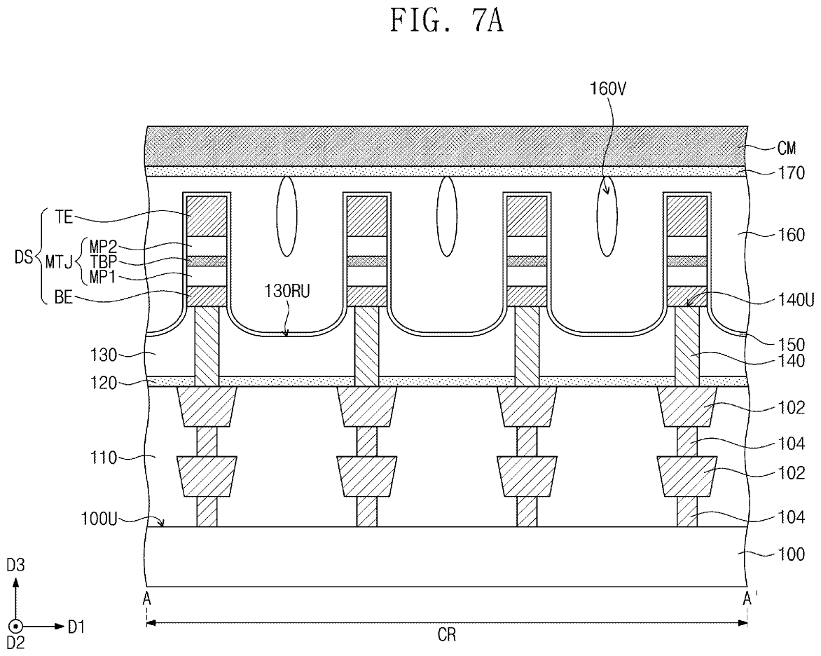

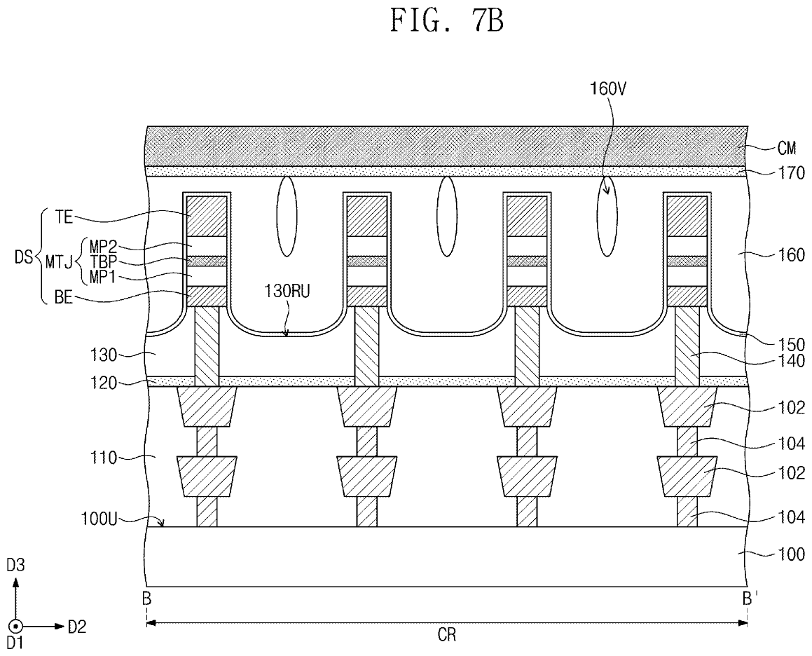

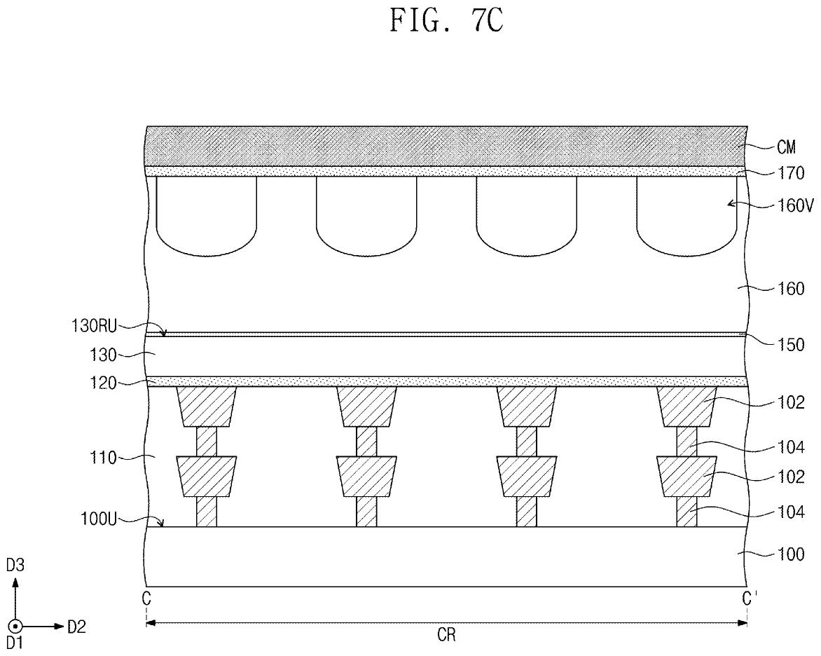

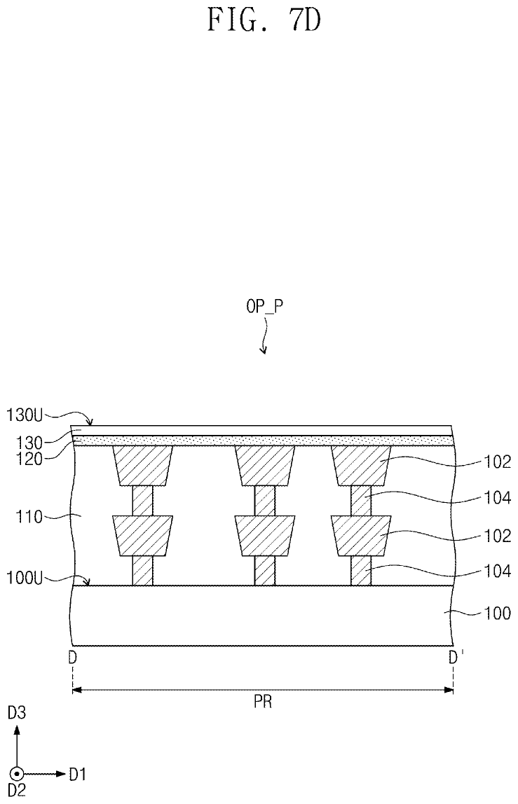

Referring to FIGS. 2 and 7A to 7D, a cell mask pattern CM may be formed on the upper dielectric layer 170 on the cell region CR. The cell mask pattern CM may expose the upper dielectric layer 170 on the peripheral region PR. The cell mask pattern CM may be, for example, a photoresist pattern.

A peripheral opening OP_P may be formed on the peripheral region PR, and may expose the top surface 130U of the second lower dielectric layer 130 on the peripheral region PR. The formation of the peripheral opening OP_P may include using the cell mask pattern CM as an etching mask to perform an etching process that removes the upper dielectric layer 170, the cell dielectric layer 160, and the capping dielectric layer 150 on the peripheral region PR. In the etching process, the upper dielectric layer 170, the cell dielectric layer 160, and the capping dielectric layer 150 on the peripheral region PR may be removed to expose the top surface 130U of the second lower dielectric layer 130 on the peripheral region PR.

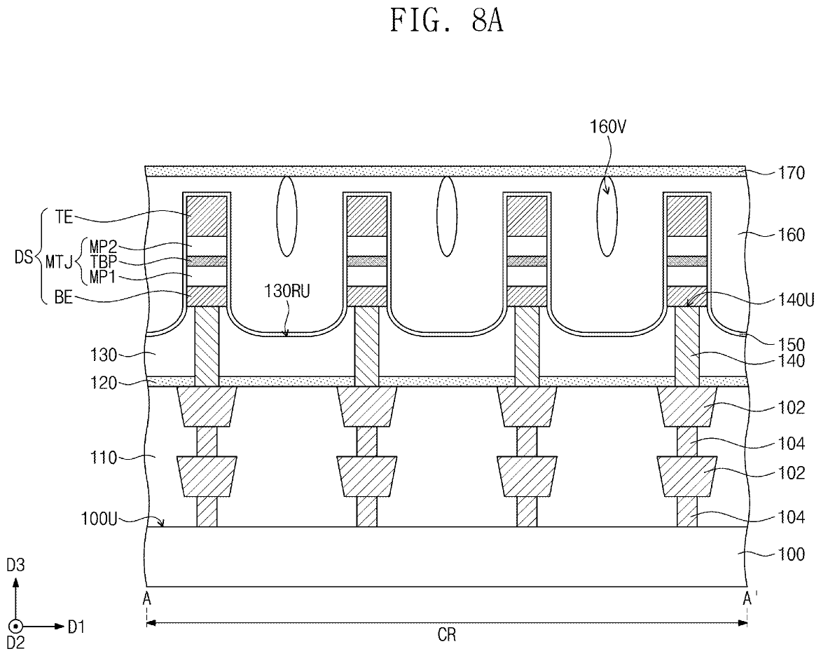

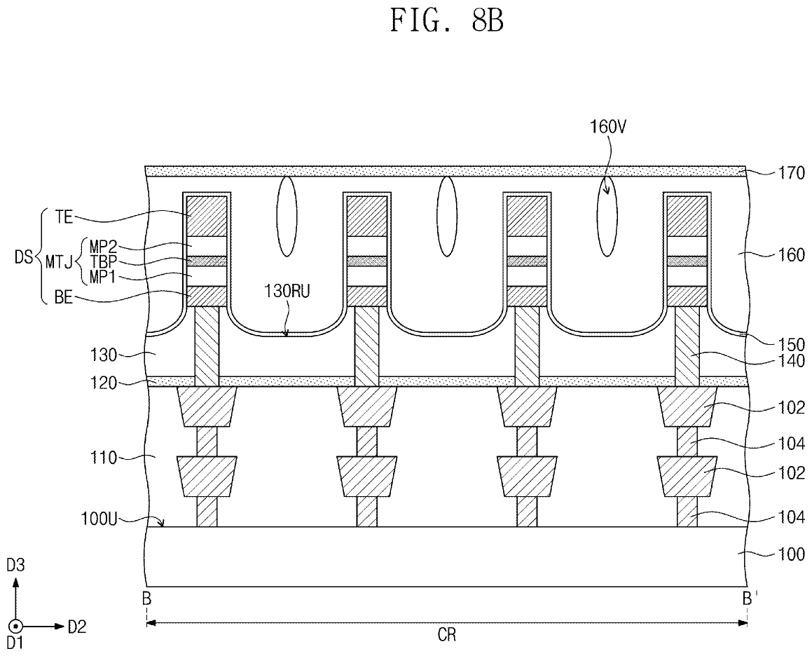

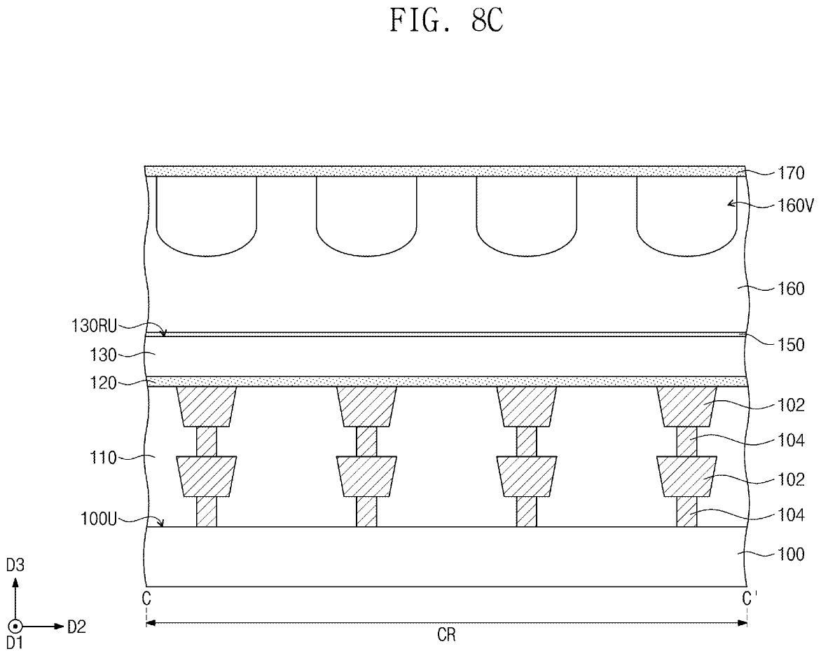

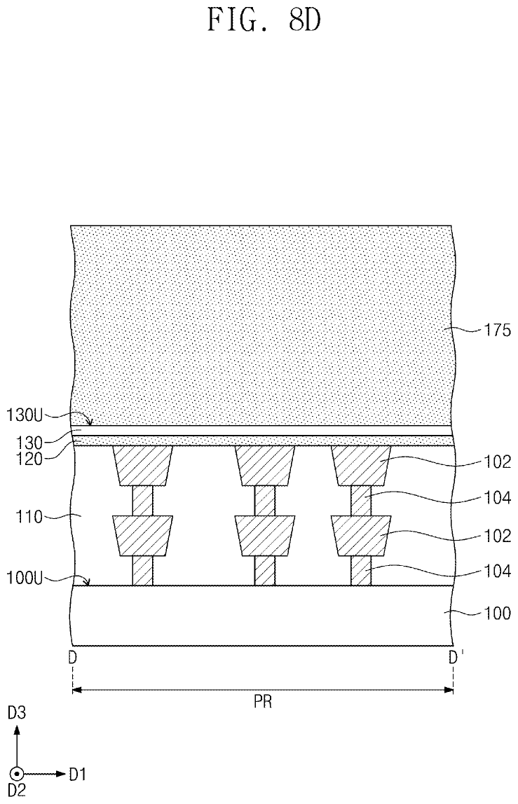

Referring to FIGS. 2 and 8A to 8D, the cell mask pattern CM may be removed. The cell mask pattern CM may be removed by, for example, an ashing and/or a strip process.

A peripheral dielectric layer 175 may be formed to fill the peripheral opening OP_P. The peripheral dielectric layer 175 may be in contact with the top surface 130U of the second lower dielectric layer 130 on the peripheral region PR. The peripheral dielectric layer 175 may include a dielectric material whose dielectric constant is less than that of the cell dielectric layer 160 and that of the upper dielectric layer 170. The formation of the peripheral dielectric layer 175 may include, for example, forming a dielectric layer to fill the peripheral opening OP_P and planarizing the dielectric layer until a top surface of the upper dielectric layer 170 is exposed. The dielectric layer may be formed by using, for example, a chemical vapor deposition process. The planarization process may be performed by using, for example, at least one selected from an etch-back process and a chemical mechanical polishing process.

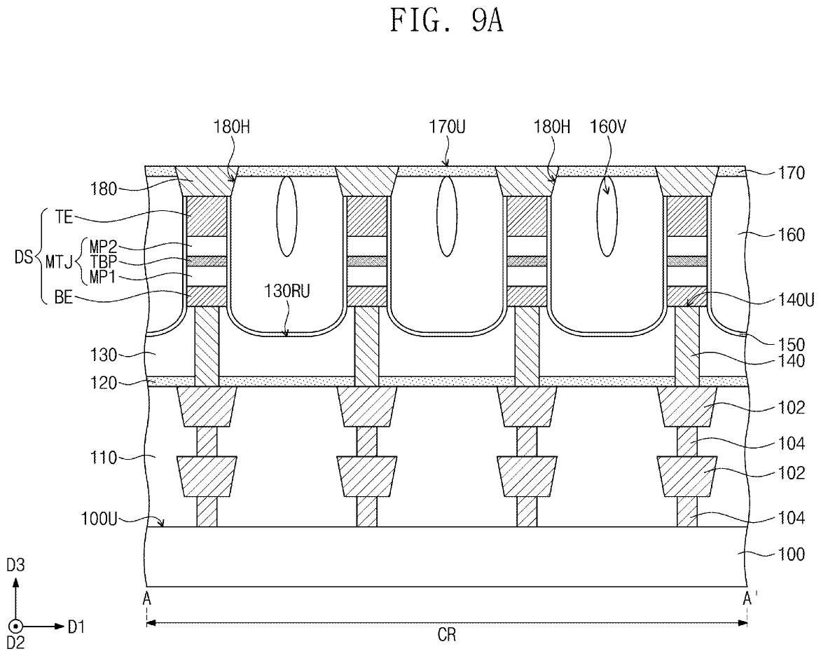

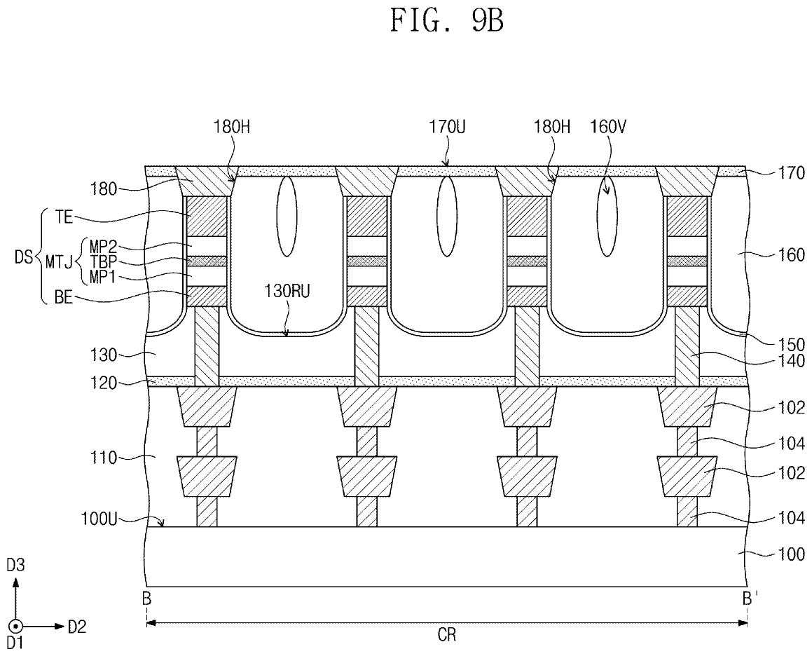

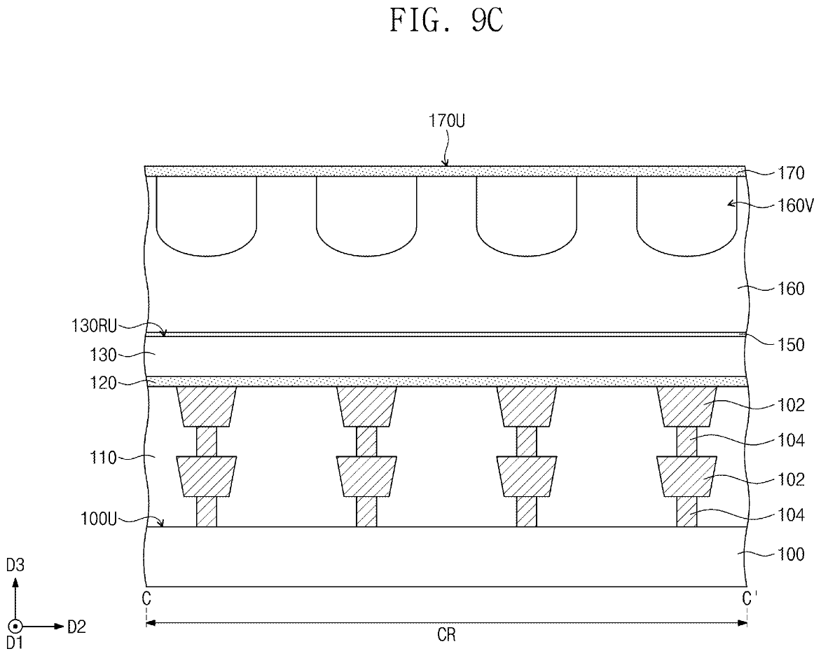

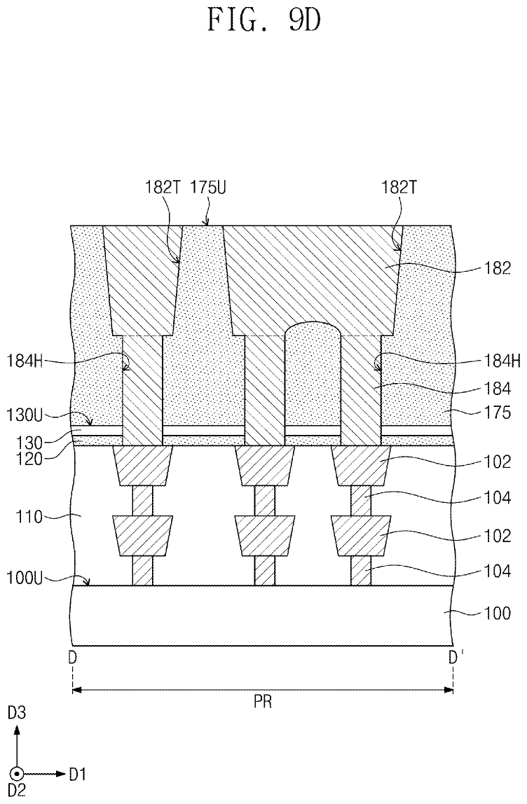

Referring to FIGS. 2 and 9A to 9D, upper conductive contacts 180 may be formed on the cell region CR. The upper conductive contacts 180 may be correspondingly formed on the data storage patterns DS, and may be spaced apart from each other in a first direction D1 and a second direction D2. The formation of the upper conductive contacts 180 may include correspondingly forming upper contact holes 180H on the data storage patterns DS, forming a conductive layer on the upper dielectric layer 170 that fills the upper contact holes 180H, and planarizing the conductive layer until a top surface 170U of the upper dielectric layer 170 is exposed. The upper contact holes 180H may be spaced apart from each other in the first direction D1 and the second direction D2 on the data storage patterns DS. The upper contact holes 180H may penetrate (i.e., extend into) the upper dielectric layer 170, an upper portion of the cell dielectric layer 160, and the capping dielectric layer 150, and may correspondingly expose the top electrodes TE of the data storage patterns DS.

Peripheral conductive lines 182 and peripheral conductive contacts 184 may be formed in the peripheral dielectric layer 175 on the peripheral region PR. The formation of the peripheral conductive lines 182 and the peripheral conductive contacts 184 may include forming peripheral trenches 182T that penetrate (i.e., extend into) an upper portion of the peripheral dielectric layer 175, forming peripheral holes 184H that extend toward the substrate 100 from bottom surfaces of the peripheral trenches 182T, forming a conductive layer on the peripheral dielectric layer 175 that fills the peripheral trenches 182T and the peripheral holes 184H, and planarizing the conductive layer until a top surface 175U of the peripheral dielectric layer 175 is exposed. Each of the peripheral holes 184H may penetrate (i.e., extend into) a lower portion of the peripheral dielectric layer 175, the second lower dielectric layer 130, and the first lower dielectric layer 120 on the peripheral region PR, thereby exposing the top surface of a corresponding one of the uppermost wiring lines 102.

According to some embodiments, the upper conductive contacts 180, the peripheral conductive lines 182, and the peripheral conductive contacts 184 may be formed simultaneously with each other. For example, the formation of the upper conductive contacts 180, the peripheral conductive lines 182, and the peripheral conductive contacts 184 may include forming a conductive layer on the upper dielectric layer 170 and the peripheral dielectric layer 175 to fill the upper contact holes 180H, the peripheral trenches 182T, and the peripheral holes 184H, and planarizing the conductive layer until the top surface 170U of the upper dielectric layer 170 is exposed and the top surface 175U of the peripheral dielectric layer 175 is exposed.

Referring back to FIGS. 2 and 3A to 3D, an interlayer dielectric layer 190 may be formed on the cell region CR and the peripheral region PR, and may be on (e.g., may cover) the top surface 170U of the upper dielectric layer 170, the top surfaces 180U of the upper conductive contacts 180, the top surface 175U of the peripheral dielectric layer 175, and top surfaces 182U of the peripheral conductive lines 182.

Upper vias 195 may be formed in the interlayer dielectric layer 190 on the cell region CR. The upper vias 195 may be correspondingly formed on the upper conductive contacts 180, and may be spaced apart from each other in the first direction D1 and the second direction D2. The upper vias 195 may penetrate (i.e., extend into) the interlayer dielectric layer 190 and may be correspondingly connected to the upper conductive contacts 180.

Upper conductive lines 200 may be formed on the interlayer dielectric layer 190 on the cell region CR. The upper conductive lines 200 may extend in the first direction D1, and may be spaced apart from each other in the second direction D2. Each of the upper conductive lines 200 may have a linear shape elongated in the first direction D1. Each of the upper conductive lines 200 may be connected to corresponding ones of the upper vias 195 that are spaced apart from each other in the first direction D1, and may be electrically connected through the corresponding upper vias 195 to corresponding ones of the upper conductive contacts 180 that are spaced apart from each other in the first direction D1.

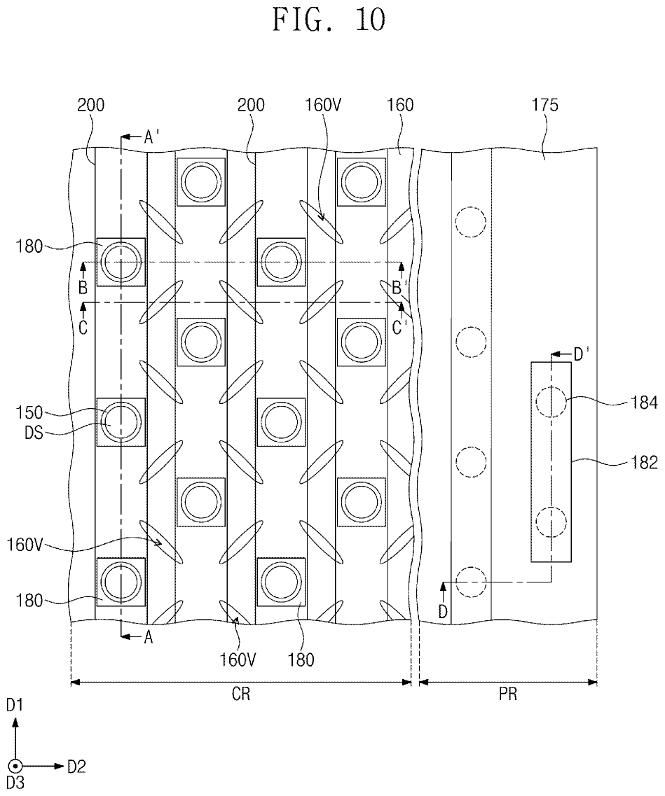

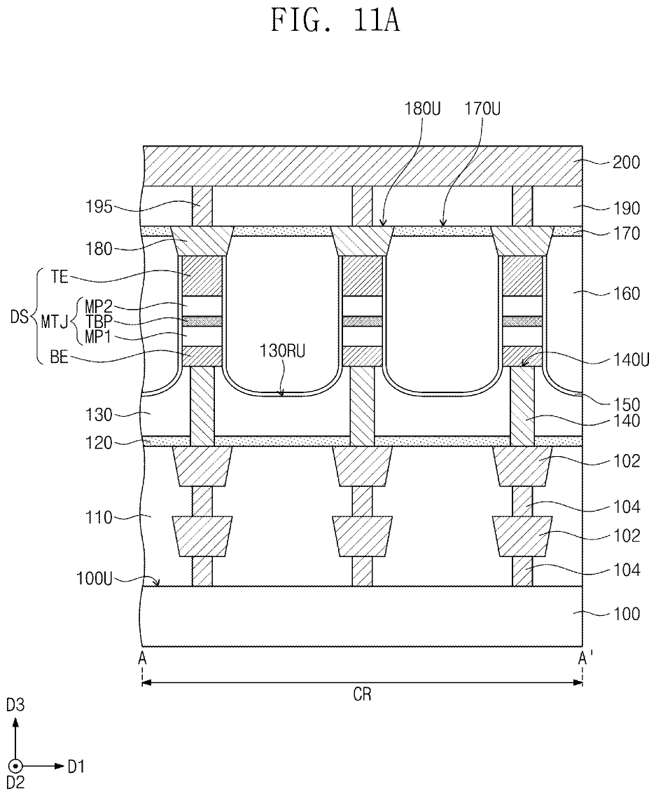

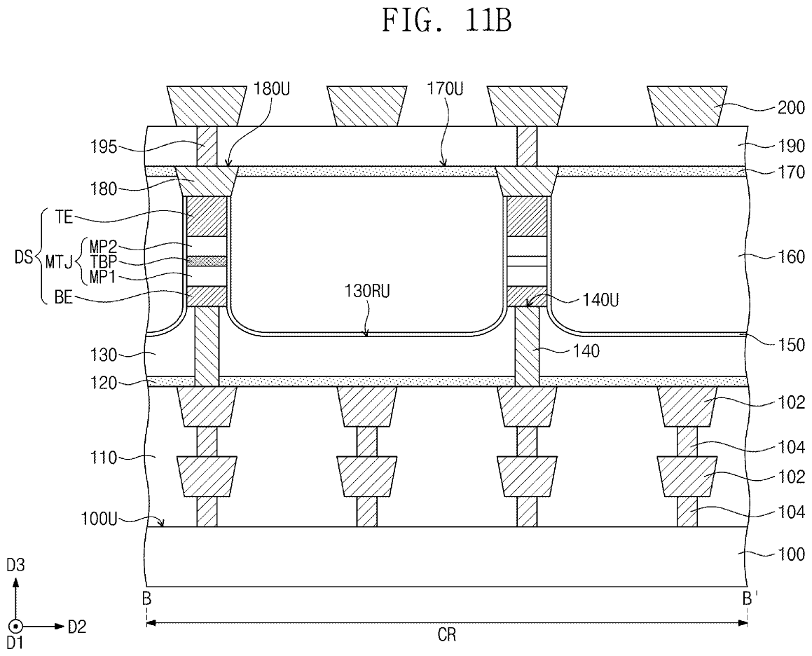

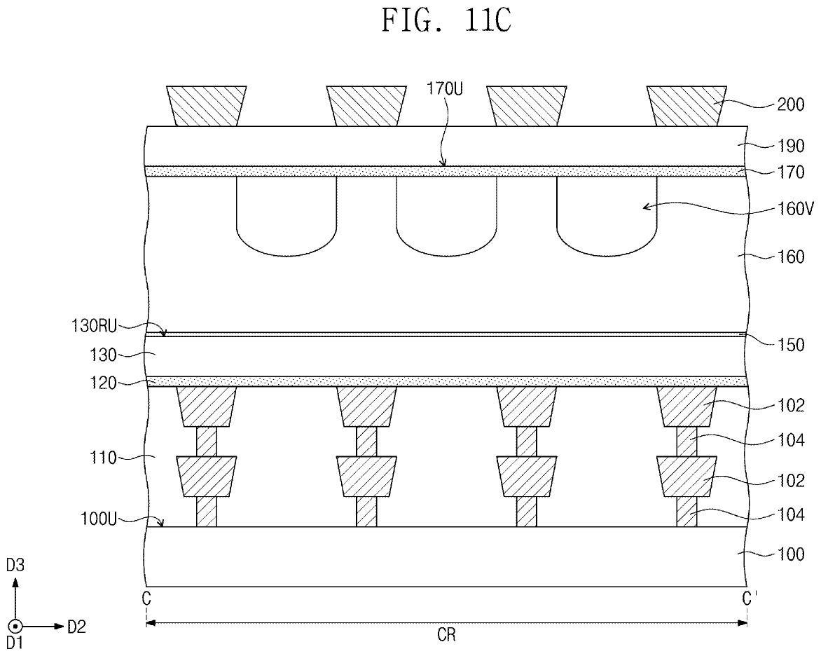

FIG. 10 illustrates a plan view showing a semiconductor device according to some embodiments of the present inventive concepts. FIGS. 11A, 11B, and 11C illustrate cross-sectional views respectively taken along lines A-A′, B-B′, and C-C′ of FIG. 10. A cross-sectional view taken along line D-D′ of FIG. 10 may be substantially the same as that of FIG. 3D. For brevity of description, redundant or repetitive descriptions that overlap with the discussion of the semiconductor device described with reference to FIGS. 1, 2, 3A to 3D, 4A, and 4B will be briefly mentioned or omitted.

Referring to FIGS. 10, 11A to 11C, and 3D, data storage patterns DS may be disposed on the second lower dielectric layer 130 on the cell region CR, and may be spaced apart from each other in the first direction D1 and the second direction D2. Among the data storage patterns DS, the data storage patterns DS in a first column may be spaced apart from each other in the first direction D1, and the data storage patterns DS in a second column may be spaced apart from each other in the first direction D1 (e.g., see FIG. 10). For example, in FIG. 10, a column direction may be the first direction D1, and the first and second columns may be adjacent to each other in the second direction D2. The data storage patterns DS in the second column may neighbor in the second direction D2 with the data storage patterns DS in the first column, and may be offset in the first direction D1 from the data storage patterns DS in the first column. In other words, the data storage patterns DS in the second column may not be aligned with the data storage patterns DS in the first column along the second direction D2. For example, the data storage patterns DS in the second column may be spaced apart from the data storage patterns DS in the first column in the first direction D1.

A cell dielectric layer 160 may be disposed on the second lower dielectric layer 130 on the cell region CR, and may be on (e.g., may cover) the data storage patterns DS. The cell dielectric layer 160 may fill a space between the data storage patterns DS. An upper dielectric layer 170 may be disposed on the cell dielectric layer 160 on the cell region CR.

A plurality of voids 160V may be disposed in the cell dielectric layer 160 and between the data storage patterns DS. The plurality of voids 160V may be spaced apart from each other in the first direction D1 and the second direction D2 on the second lower dielectric layer 130. The plurality of voids 160V may be disposed below the upper dielectric layer 170, and may be disposed on the second lower dielectric layer 130 and the capping dielectric layer 150. For example, the plurality of voids 160V may be between the upper dielectric layer 170 and the second lower dielectric layer 130. Each of the plurality of voids 160V may vertically overlap in the third direction D3 with the recessed top surface 130RU of the second lower dielectric layer 130. Ones of the plurality of voids 160V may be spaced apart from each other in the first direction D1 between the data storage patterns DS in the first column and the data storage patterns DS in the second column. For example, at least one of the plurality of voids 160V may be between one of the data storage patterns DS in the first column and one of the data storage patterns DS in the second column in a direction that is oblique to the first and second directions D1 and D2 (e.g., a diagonal direction).

Upper conductive contacts 180 may be correspondingly disposed on the data storage patterns DS, and may be spaced apart from each other in the first direction D1 and the second direction D2. Among the upper conductive contacts 180, the upper conductive contacts 180 in a first column may be spaced apart from each other in the first direction D1, and the upper conductive contacts 180 in a second column may be spaced apart from each other in the first direction D1 (e.g., see FIG. 10). The upper conductive contacts 180 in the second column may neighbor in the second direction D2 with the upper conductive contacts 180 in the first column, and may be offset in the first direction D1 from the upper conductive contacts 180 in the first column. In other words, the upper conductive contacts 180 in the second column may not be aligned with the upper conductive contacts 180 in the first column along the second direction D2. For example, the upper conductive contacts 180 in the second column may be spaced apart from the upper conductive contacts 180 in the first column in the first direction D1. The upper conductive contacts 180 in the first column may be correspondingly disposed on and connected to the data storage patterns DS in the first column. The upper conductive contacts 180 in the second column may be correspondingly disposed on and connected to the data storage patterns DS in the second column.

The upper conductive contacts 180 may be spaced horizontally (e.g., in the first direction D1 or the second direction D2) apart from the plurality of voids 160V between the data storage patterns DS. Ones of the plurality of voids 160V may be spaced apart from each other in the first direction D1 between the upper conductive contacts 180 in the first column and the upper conductive contacts 180 in the second column. Each of the plurality of voids 160V may not overlap in the third direction D3 with any of the upper conductive contacts 180. That is, each of the plurality of voids 160V may be free of overlap with the upper conductive contacts 180 in the third direction D3.

An interlayer dielectric layer 190 may be disposed on the cell region CR and the peripheral region PR, and may be on (e.g., may cover) a top surface 170U of the upper dielectric layer 170, top surfaces 180U of the upper conductive contacts 180, a top surface 175U of the peripheral dielectric layer 175, and top surfaces 182U of the peripheral conductive lines 182.

Upper vias 195 may be disposed in the interlayer dielectric layer 190 on the cell region CR. The upper vias 195 may be correspondingly disposed on the upper conductive contacts 180, and may be spaced apart from each other in the first direction D1 and the second direction D2. The upper vias 195 may be correspondingly connected to the upper conductive contacts 180.

Upper conductive lines 200 may be disposed on the interlayer dielectric layer 190 on the cell region CR. The upper conductive lines 200 may extend in the first direction D1, and may be spaced apart from each other in the second direction D2. Each of the upper conductive lines 200 may be connected to corresponding ones of the upper vias 195 that are spaced apart from each other in the first direction D1. One of the upper conductive lines 200 may be electrically connected through the corresponding upper vias 195 to the upper conductive contacts 180 in the first column. Another one of the upper conductive lines 200 may be electrically connected through the corresponding upper vias 195 to the upper conductive contacts 180 in the second column.

Except that mentioned above, the semiconductor device may be substantially the same as the semiconductor device described with reference to FIGS. 1, 2, 3A to 3D, 4A, and 4B.

According to the present inventive concepts, an increase in integration of a semiconductor device may cause a reduction in distance between data storage patterns, and as a result, a plurality of voids may be formed in a cell dielectric layer between the data storage patterns. Upper conductive contacts may be correspondingly disposed on the data storage patterns, and may be spaced apart from each other in a first direction and a second direction. The upper conductive contacts may be spaced horizontally (e.g., in the first direction or the second direction) apart from the plurality of voids between the data storage patterns. The plurality of voids may be disposed below an upper dielectric layer and may vertically overlap with the upper dielectric layer between the upper conductive contacts. In this case, during the formation of the upper conductive contacts, the plurality of voids may be blocked by the upper dielectric layer, and as a result, may be prevented from being filled with a conductive material. Accordingly, no bridge failure may occur between the upper conductive contacts.

In conclusion, a semiconductor device may be provided which is capable of easily achieving high integration and minimizing process defects.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

The aforementioned description provides example embodiments for explaining the present inventive concepts. Therefore, the present inventive concepts are not limited to the embodiments described above, and it will be understood by one of ordinary skill in the art that variations in form and detail may be made therein without departing from the scope of the present inventive concepts.

What is claimed is:

1. A semiconductor device, comprising:
a lower dielectric layer on a substrate;
a plurality of data storage patterns on the lower dielectric layer and spaced apart from each other in a first direction and a second direction that are parallel to a top surface of the substrate, wherein the first and second directions intersect each other;
a cell dielectric layer on the lower dielectric layer and on the data storage patterns;
a plurality of voids in the cell dielectric layer and between ones of the data storage patterns;
a plurality of upper conductive contacts respectively on the data storage patterns and spaced apart from each other in the first direction and the second direction; and
a plurality of upper conductive lines on the upper conductive contacts and spaced apart from each other in the second direction, wherein the upper conductive lines extend in the first direction,
wherein each of the upper conductive lines is electrically connected to respective ones of the upper conductive contacts, and
wherein the respective ones of the upper conductive contacts are spaced apart from each other in the first direction.

2. The semiconductor device of claim 1, further comprising an upper dielectric layer on the cell dielectric layer,
wherein the plurality of voids are between the upper dielectric layer and the lower dielectric layer.

3. The semiconductor device of claim 2, wherein the upper conductive contacts extend into the upper dielectric layer and an upper portion of the cell dielectric layer and are respectively electrically connected to the data storage patterns.

4. The semiconductor device of claim 3, wherein each of the data storage patterns comprises a bottom electrode, a magnetic tunnel junction pattern, and a top electrode that are stacked in a third direction on the lower dielectric layer,
wherein the third direction is perpendicular to the top surface of the substrate,
wherein the top electrode is between the magnetic tunnel junction pattern and each of the upper conductive contacts, and
wherein each of the upper conductive contacts is in contact with the top electrode.

5. The semiconductor device of claim 3, wherein top surfaces of the upper conductive contacts are free of the upper dielectric layer thereon.

6. The semiconductor device of claim 5, further comprising an interlayer dielectric layer on the upper dielectric layer,
wherein the interlayer dielectric layer overlaps a top surface of the upper dielectric layer and extends onto the top surfaces of the upper conductive contacts.

7. The semiconductor device of claim 6, further comprising a plurality of upper vias in the interlayer dielectric layer and respectively on the upper conductive contacts,
wherein the upper vias extend into the interlayer dielectric layer and are respectively electrically connected to the upper conductive contacts,
wherein the upper conductive lines are on the interlayer dielectric layer and are electrically connected to the respective ones of the upper conductive contacts through respective ones of the upper vias, and
wherein the respective ones of the upper vias are spaced apart from each other in the first direction.

8. The semiconductor device of claim 1, wherein the lower dielectric layer has a recessed top surface that is recessed toward the substrate between the ones of the data storage patterns,
wherein each of the plurality of voids overlaps the recessed top surface of the lower dielectric layer in a third direction, and
wherein the third direction is perpendicular to the top surface of the substrate.

9. The semiconductor device of claim 8, further comprising a plurality of lower electrode contacts in the lower dielectric layer and respectively on bottom surfaces of the data storage patterns,
wherein the lower electrode contacts extend into the lower dielectric layer and are respectively electrically connected to the data storage patterns, and
wherein the recessed top surface of the lower dielectric layer is at a height in the third direction that is lower than a height of top surfaces of the lower electrode contacts in the third direction, with the top surface of the substrate providing a base reference plane.

10. The semiconductor device of claim 1, wherein the substrate comprises a cell region and a peripheral region,
wherein the lower dielectric layer is on the cell region and extends onto the peripheral region,
wherein the data storage patterns, the cell dielectric layer, the plurality of voids, the upper conductive contacts, and the upper conductive lines are on the cell region,
wherein a first portion of the lower dielectric layer on the cell region has a recessed top surface that is recessed toward the substrate between the ones of the data storage patterns,
wherein a second portion of the lower dielectric layer on the peripheral region has a top surface at a height in a third direction that is lower than a height of the recessed top surface of the first portion of the lower dielectric layer in the third direction, with the top surface of the substrate providing a base reference plane, and
wherein the third direction is perpendicular to the top surface of the substrate.

11. The semiconductor device of claim 10, further comprising a peripheral dielectric layer on the lower dielectric layer and on the peripheral region,
wherein the cell dielectric layer comprises a dielectric material having a dielectric constant that is greater than a dielectric constant of the peripheral dielectric layer.

12. A semiconductor device, comprising:
a lower dielectric layer on a substrate;
a plurality of data storage patterns on the lower dielectric layer and spaced apart from each other in a first direction parallel to a top surface of the substrate;
a cell dielectric layer on the lower dielectric layer and on the data storage patterns;
a plurality of voids in the cell dielectric layer and between ones of the data storage patterns;
a plurality of upper conductive contacts respectively on the data storage patterns and spaced apart from each other in the first direction; and
an upper conductive line that is on the upper conductive contacts and extends in the first direction,
wherein the upper conductive contacts extend into an upper portion of the cell dielectric layer and are respectively electrically connected to the data storage patterns, and
wherein the upper conductive line is electrically connected to the upper conductive contacts.

13. The semiconductor device of claim 12, further comprising an upper dielectric layer on the cell dielectric layer,
wherein the plurality of voids are between the upper dielectric layer and the lower dielectric layer.

14. The semiconductor device of claim 13, wherein the upper conductive contacts extend into the upper dielectric layer and the upper portion of the cell dielectric layer and are respectively electrically connected to the data storage patterns.

15. The semiconductor device of claim 14, wherein each of the data storage patterns comprises:
a magnetic tunnel junction pattern; and
a top electrode between the magnetic tunnel junction pattern and each of the upper conductive contacts,
wherein each of the upper conductive contacts is in contact with the top electrode.

16. The semiconductor device of claim 14, further comprising a plurality of lower electrode contacts in the lower dielectric layer and respectively on bottom surfaces of the data storage patterns,
wherein the lower electrode contacts extend into the lower dielectric layer and are respectively electrically connected to the data storage patterns,
wherein the lower dielectric layer has a recessed top surface that is recessed toward the substrate between the ones of the data storage patterns,
wherein the recessed top surface of the lower dielectric layer is at a height in a second direction that is lower than a height of top surfaces of the lower electrode contacts in the second direction, with the top surface of the substrate providing a base reference plane, and
wherein the second direction is perpendicular to the top surface of the substrate.

17. The semiconductor device of claim 16, wherein each of the plurality of voids overlaps the recessed top surface of the lower dielectric layer in the second direction.

18. The semiconductor device of claim 12, wherein the substrate comprises a cell region and a peripheral region,
wherein the lower dielectric layer is on the cell region and extends onto the peripheral region,
wherein the data storage patterns, the cell dielectric layer, the plurality of voids, the upper conductive contacts, and the upper conductive line are on the lower dielectric layer and on the cell region,
wherein the semiconductor device further comprises a peripheral dielectric layer on the lower dielectric layer and on the peripheral region, and
wherein the cell dielectric layer comprises a dielectric material having a dielectric constant that is greater than a dielectric constant of the peripheral dielectric layer.

19. The semiconductor device of claim 18, wherein a first portion of the lower dielectric layer on the cell region has a recessed top surface that is recessed toward the substrate between the ones of the data storage patterns,
wherein a second portion of the lower dielectric layer on the peripheral region has a top surface at a height in a second direction that is lower than a height of the recessed top surface of the first portion of the lower dielectric layer in the second direction, with the top surface of the substrate providing a base reference plane,
wherein the second direction is perpendicular to the top surface of the substrate, and
wherein the peripheral dielectric layer is in contact with the top surface of the second portion of the lower dielectric layer.

20. A semiconductor device, comprising:
a lower dielectric layer on a substrate;
a plurality of data storage patterns on the lower dielectric layer and spaced apart from each other in a first direction parallel to a top surface of the substrate;
a cell dielectric layer on the lower dielectric layer and on the data storage patterns;
a plurality of voids in the cell dielectric layer;
a plurality of upper conductive contacts respectively on the data storage patterns and spaced apart from each other in the first direction; and
an upper conductive line that is on the upper conductive contacts and extends in the first direction,
wherein the upper conductive line is electrically connected to the upper conductive contacts, and
wherein the plurality of voids are free of overlap with the upper conductive contacts in a second direction perpendicular to the top surface of the substrate.
